(19) United States
(12) Patent Application Publication
(10) Pub. No.: US 2016/0257842 A1
(43) Pub. Date: Sep. 8, 2016

(54) COMPOSITION FOR RESIST UNDERLAYER FILM FORMATION, RESIST UNDERLAYER FILM, AND PRODUCTION METHOD OF PATTERNED SUBSTRATE

(71) Applicant: JSR CORPORATION, Tokyo (JP)

(72) Inventors: Goji WAKAMATSU, Tokyo (JP); Naoya NOSAKA, Tokyo (JP); Yuushi MATSUMURA, Tokyo (JP); Yoshio TAKIMOTO, Tokyo (JP); Tsubasa ABE, Tokyo (JP); Toru KIMURA, Tokyo (JP)

(73) Assignee: JSR CORPORATION, Tokyo (JP)

(21) Appl. No.: 15/059,372

(22) Filed: Mar. 3, 2016

(30) Foreign Application Priority Data
Mar. 3, 2015 (JP) 2015-041843
Oct. 21, 2015 (JP) 2015-207573

(51) Int. Cl. C09D 161/14; G03F 7/36; G03F 7/11

(52) U.S. Cl. CPC C09D 161/14; G03F 7/11; G03F 7/36

(57) ABSTRACT

A composition comprises a compound and a solvent. The compound comprises a carbon-carbon triple bond-containing group, and at least one partial structure having an aromatic ring. A total number of benzene nuclei constituting the aromatic ring in the at least one partial structure is no less than 4. The at least one partial structure preferably comprises a partial structure represented by formula (1). The sum of p1, p2, p3 and p4 is preferably no less than 1. At least one of R¹ to R⁴ preferably represents a monovalent carbon-carbon triple bond-containing group. The at least one partial structure also preferably comprises a partial structure represented by formula (2). The sum of q1, q2, q3 and q4 is preferably no less than 1. At least one of R⁵ to R⁸ preferably represents a monovalent carbon-carbon triple bond-containing group.

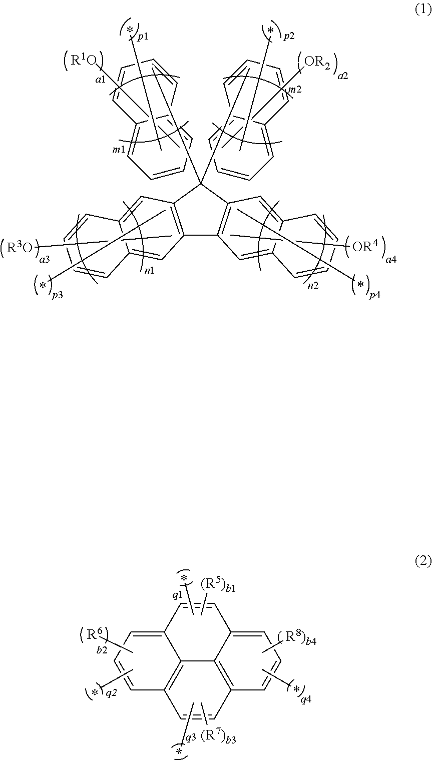

### CROSS-REFERENCE TO RELATED APPLICATIONS

The present application claims priority to Japanese Patent Application No. 2015-041843, filed Mar. 3, 2015, and to Japanese Patent Application No. 2015-207573, filed Oct. 21, 2015. The contents of these applications are incorporated herein by reference in their entirety.

### BACKGROUND OF THE INVENTION

1. Field of Invention

The present invention relates to a composition for resist underlayer film formation, a resist underlayer film, and a production method of a patterned substrate.

2. Discussion of the Background

In manufacturing semiconductor devices, multilayer resist processes have been employed for attaining a high degree of integration. In these processes, a composition for resist underlayer film formation is first coated on the upper face side of a substrate to provide a resist underlayer film, and then a resist composition is coated on the upper face side of the resist underlayer film to provide a resist film. Thereafter, the resist film is exposed through a mask pattern or the like, and developed with an appropriate developer solution to form a resist pattern. Subsequently, the resist underlayer film is dry-etched using the resist pattern as a mask, and further the substrate is etched using the resulting resist underlayer film pattern as a mask to form a desired pattern on the substrate, thereby enabling a patterned substrate to be obtained. Resist underlayer films used in such multilayer resist processes are required to have optical characteristics such as a favorable refractive index and extinction coefficient, as well as general characteristics such as solvent resistance and etching resistance.

In recent years, in order to further increase the degree of integration, miniaturization of patterns has been further in progress. Also in connection with the multilayer resist processes described above, various characteristics as in the following are demanded for resist underlayer films formed, as well as compositions for forming the same. To meet these demands, structures of compounds, etc., contained in the composition, and functional groups included in the compounds have been extensively investigated (see Japanese Unexamined Patent Application, Publication No. 2004-177668).

Moreover, the multilayer resist processes involving a procedure of forming a hard mask as an intermediate layer on the resist underlayer film has been studied recently. Specifically, since an inorganic hard mask is formed on a resist underlayer film using a CVD technique according to this procedure, particularly in a case where a nitride inorganic hard mask is formed, the temperature is elevated to be as high as at least 300° C., and typically no less than 400° C., and thus, the resist underlayer film is required to have superior heat resistance.

Still further, patterns are more frequently formed recently on a substrate having a plurality of types of trenches, in particular trenches having aspect ratios that differ from each other, and the resist underlayer film formed is desired to sufficiently fill these trenches.

### SUMMARY OF THE INVENTION

According to one aspect of the present invention, a composition comprises a compound and a solvent. A compound comprises: a carbon-carbon triple bond-containing group; and at least one partial structure having an aromatic ring. A total number of benzene nuclei constituting the aromatic ring in the at least one partial structure is no less than 4.

According to another aspect of the present invention, a resist underlayer film is formed from the composition.

According to further aspect of the present invention, a method for producing a patterned substrate, comprises applying the composition on an upper face side of a substrate to form a resist underlayer film. A resist pattern is formed on an upper face side of the resist underlayer film. The resist underlayer film and the substrate are etched, by each separate etching operation using the resist pattern as a mask such that the substrate has a pattern.

### DESCRIPTION OF THE EMBODIMENTS

According to an embodiment of the invention made for solving the aforementioned problems, a composition for resist underlayer film formation contains: a compound (hereinafter, may be also referred to as “(A) compound” or “compound (A)”) having a carbon-carbon triple bond-containing group (hereinafter, may be also referred to as “specific group (A)”), and a partial structure (hereinafter, may be also referred to as “partial structure (A)”) having an aromatic ring (hereinafter, may be also referred to as “aromatic ring (A)”), the total number of benzene nuclei constituting the aromatic ring (A) in the partial structure (A) being no less than 4; and a solvent (hereinafter, may be also referred to as “(B) solvent” or “solvent (B)”).

According to another embodiment of the invention made for solving the aforementioned problems, a resist underlayer film is formed from the composition for resist underlayer film formation according to the above embodiment of the present invention.

According to still another embodiment of the invention made for solving the aforementioned problems, a method for producing a patterned substrate includes the steps of: forming a resist underlayer film on the upper face side of a substrate; forming a resist pattern on the upper face side of the resist underlayer film; and etching at least the resist underlayer film and the substrate, by each separate etching operation using the resist pattern as a mask such that the substrate has a pattern, in which the resist underlayer film is formed from the composition for resist underlayer film formation according to the embodiment of the present invention.

The term “partial structure” as referred to herein means a structure derived from a precursor compound used in the synthesis of the compound (A) (except for a compound that provides a linking group described later). The term “benzene nucleus” or “benzene nuclei” as referred to means carbocyclic six-membered ring(s) having aromaticity. Each of six-membered rings constituting a fused ring also falls under the category of the benzene nuclei. For example, the number of benzene nuclei in a naphthalene ring is 2.

The composition for resist underlayer film formation according to the embodiment of the present invention enables the use of PGMEA or the like as a solvent, and can form a resist underlayer film that is superior in solvent resistance, etching resistance, heat resistance and filling performances.

Specifically, since the composition enables the use of PGMEA, the application properties of the composition on the substrate is good, and formation of a uniform resist underlayer film can be easy. Since the resist underlayer film formed from the composition has sufficient heat resistance, sublimation of a component in the resist underlayer film and adherence of the sublimed component to the substrate can be suppressed. Further, since filling performances of the composition are sufficient, cavities (void) of the resist underlayer film formed from the composition can be decreased. The resist underlayer film according to the another embodiment of the present invention is superior in solvent resistance, etching resistance, heat resistance and filling performances. The method for producing a patterned substrate according to the still another embodiment of the present invention enables a patterned substrate having a superior pattern configuration to be obtained using the superior resist underlayer film thus formed. Therefore, these can be suitably used in manufacture of semiconductor devices, and the like in which further progress of miniaturization is expected in the future. Hereinafter, embodiments of the present invention are explained in detail.

### Composition for Resist Underlayer Film Formation

The composition for resist underlayer film formation according to an embodiment of the present invention contains the compound (A) and the solvent (B). The composition for resist underlayer film formation may contain (C) an acid generating agent as a favorable component, and may contain other optional component within a range not leading to impairment of the effects of the present invention. Hereinafter, each component will be described.

### (A) Compound

The compound (A) has the specific group (A) and the partial structure (A). Since the compound (A) has the specific group (A) and the partial structure (A), the composition for resist underlayer film formation enables the use of PGMEA or the like as a solvent, and can form a resist underlayer film that is superior in solvent resistance, etching resistance, heat resistance and filling performances. Although not necessarily clarified, the reason for the composition for resist underlayer film formation achieving the aforementioned effects due to the compound (A) having the constitution described above is inferred as in the following, for example. Specifically, since the compound (A) has the specific group (A) containing a carbon-carbon triple bond and the partial structure (A) having the aromatic ring (A), and the total number of benzene nuclei in the partial structure (A) is no less than the predetermined number, the solubility of the compound (A) in a solvent such as PGMEA can be increased. Since the composition for resist underlayer film formation enables the use of such a solvent, and the partial structure (A) of the compound (A) has the predetermined number of or more benzene nuclei, the filling performances of the resist underlayer film can be improved. In addition, it is inferred that since the compound (A) has the specific group (A), a higher order cross-linked structure can be formed in the formation of the resist underlayer film. Consequently, the resist underlayer film would be superior in solvent resistance and etching resistance. Further, since the partial structure (A) of the compound (A) has the predetermined number of or more benzene nuclei, the resist underlayer film is also superior in heat resistance.

The compound (A) may have other partial structure than the partial structure (A) in addition thereto. In addition, in a case where the compound (A) has a plurality of the partial structures, the plurality of the partial structures may be linked to one another through a linking group (hereinafter, may be also referred to as “linking group (a)”). Hereinafter, the specific group (A), the partial structure (A), the other partial structure than the partial structure (A), and the linking group (a) will be described.

### Specific Group (A)

The specific group (A) is a carbon-carbon triple bond-containing group. The binding site of the specific group (A) is not particularly limited as long as the specific group (A) is present in the compound (A). Moreover, the specific group (A) may be either a monovalent group or a group having a valency of no less than two. For example, the specific group (A) may be present either in the partial structure (A) described later, or in the linking group; however, in light of further enhancement of the heat resistance and the filling performances of the resist underlayer film, the specific group (A) is present preferably in the partial structure (A), more preferably in a partial structure (I) or a partial structure (II) described later, and still more preferably in the partial structure (I).

Examples of the specific group (A) include:

alkynyl groups such as an ethynyl group, a propyn-1-yl group, a propargyl group, a butyn-1-yl group, a butyn-3-yl group and a butyn-4-yl group;

groups having an aromatic ring and a triple bond, such as a phenylethynyl group and a phenylpropargyl group; and the like. In light of enhanced ease of crosslinking of molecules of the compound (A), the specific group (A) is preferably an alkynyl group, and more preferably a propargyl group.

The lower limit of the number of specific groups (A) with respect to 1 mol of the entirety of the partial structures constituting the compound (A) is preferably 0.1 mol, more preferably 0.5 mol, still more preferably 0.8 mol, and particularly preferably 1.1 mol. The upper limit of the number of specific groups (A) is preferably 5 mol, more preferably 4 mol, still more preferably 3 mol, and particularly preferably 2.5 mol. When the number of specific groups (A) falls within the above range, the crosslinkability of the compound (A) in the formation of the resist underlayer can be more appropriately adjusted, and consequently the solvent resistance, the etching resistance, the heat resistance and the filling performances of the resist underlayer film can be more enhanced. The compound (A) may have one, or two or more types of the specific group (A).

### Partial Structure (A)

The partial structure (A) has the aromatic ring (A). The total number of benzene nuclei constituting the aromatic ring (A) in the partial structure (A) is no less than 4.

Aromatic Ring (A)

The aromatic ring (A) is a carbocyclic ring having aromaticity. Examples of the aromatic ring (A) include a benzene ring, a naphthalene ring, an anthracene ring, a phenanthrene ring, a pyrene ring, a chrysene ring, a tetracene ring, a perylene ring and a pentacene ring.

The lower limit of the number of carbon atoms in the aromatic ring (A) is typically 6, preferably 8, and more preferably 10. The upper limit of the number of carbon atoms is preferably 30, more preferably 24, and still more preferably 18.

The lower limit of the number of aromatic rings (A) included in the partial structure (A) is typically 1, preferably 2, more preferably 3, and still more preferably 4. The upper limit of the number is preferably 8, and more preferably 6.

The lower limit of the total number of carbon atoms included in the aromatic ring (A) in the partial structure (A) is typically 16, preferably 20, and more preferably 24. The upper limit of the total number is preferably 50, more preferably 40, and still more preferably 32.

The lower limit of the total number of benzene nuclei constituting the aromatic ring (A) in the partial structure (A) is 4, preferably 5, and more preferably 6. The upper limit of the total number is preferably 12, more preferably 10, and still more preferably 8. When the total number of benzene nuclei falls within the above range, the solvent resistance, the etching resistance and the heat resistance of the resist underlayer film can be further enhanced. The compound (A) may have one, or two or more types of the aromatic ring (A).

A group other than the hydrogen atom such as, e.g., the specific group (A), a carbon-carbon double bond-containing group, an alkyl group, an hydroxy group or an alkoxy group may bond to any of the carbon atoms constituting the ring of the aromatic ring (A).

The partial structure (A) is exemplified by a first partial structure represented by the following formula (1) (hereinafter, may be also referred to as “partial structure (I)”), a second partial structure represented by the following formula (2) (hereinafter, may be also referred to as “partial structure (II)”), and the like.

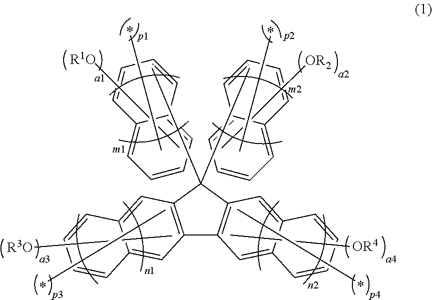

In the above formula (1), R¹ to R⁴ each independently represent a hydrogen atom, a monovalent carbon-carbon triple bond-containing group or a monovalent carbon-carbon double bond-containing group; m1 and m2 are each independently an integer of 0 to 2; a1 and a2 are each independently an integer of 0 to 9; n1 and n2 are each independently an integer of 0 to 2; a3 and a4 are each independently an integer of 0 to 8, wherein in a case where R¹ to R⁴ are each present in a plurality of number, a plurality of R¹s may be identical or different, a plurality of R²s may be identical or different, a plurality of R³s may be identical or different, and a plurality of R⁴s may be identical or different; p1 and p2 are each independently an integer of 0 to 9; p3 and p4 are each independently an integer of 0 to 8, wherein the sum of p1, p2, p3 and p4 is no less than 0, the sum of a1 and p1 and the sum of a2 and p2 are each no greater than 9, and the sum of a3 and p3 and the sum of a4 and p4 are each no greater than 8; and * denotes a binding site to a moiety other than the partial structure (I) in the compound (A).

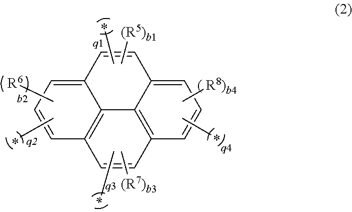

In the above formula (2), R⁵ to R⁸ each independently represent an alkyl group, a hydroxy group, an alkoxy group, a monovalent carbon-carbon triple bond-containing group or a monovalent carbon-carbon double bond-containing group; b1 and b3 are each independently an integer of 0 to 2; b2 and b4 are each independently an integer of 0 to 3, wherein in a case where R⁵ to R⁸ are each present in a plurality of number, a plurality of R⁵s may be identical or different, a plurality of R⁶s may be identical or different, a plurality of R⁷s may be identical or different, and a plurality of R⁸s may be identical or different; q1 and q3 are each independently an integer of 0 to 2; q2 and q4 are each independently an integer of 0 to 3, wherein the sum of q1, q2, q3 and q4 is no less than 0, the sum of b1 and q1 and the sum of b3 and q3 are each no greater than 2, the sum of b2 and q2 and the sum of b4 and q4 are each no greater than 3; and * denotes a binding site to a moiety other than the partial structure (II) in the compound (A).

The monovalent carbon-carbon triple bond-containing group which may be represented by R¹ to R⁴ in the above formula (1) is exemplified by the monovalent groups among the groups exemplified in connection with the specific group (A), and the like. Of these, the alkynyl groups are preferred, and the propargyl group is more preferred.

Examples of the monovalent carbon-carbon double bond-containing group which may be represented by R¹ to R⁴ include:

alkenyl groups such as an ethenyl group, a propen-1-yl group, a propen-2-yl group, a propen-3-yl group, a buten-1-yl group, a buten-2-yl group, a buten-3-yl group and a buten-4-yl group;

group having an aromatic ring and a double bond, such as a phenylethenyl group and a phenylpropenyl group; and the like.

It is preferred that at least one of R¹ to R⁴ represents the carbon-carbon triple bond-containing group, and it is more preferred that R¹ and R² represent the carbon-carbon triple bond-containing group. When the specific group (A) is thus included in the partial structure (I), the crosslinkability of molecules of the compound (A) may be more improved, and consequently the solvent resistance, the etching resistance, the heat resistance and the filling performances of the resist underlayer film may be more improved.

In the above formula (1), m1 and m2 are each independently preferably 0 or 1; a1 and a2 are each independently preferably an integer of 0 to 2, more preferably 0 or 1, and still more preferably 1; a3 and a4 are each independently preferably an integer of 0 to 2, more preferably 0 or 1, and still more preferably 0; p1 and p2 are each independently preferably an integer of 0 to 2, more preferably 0 or 1, and still more preferably 1; and p3 and p4 are each independently preferably an integer of 0 to 2, more preferably 0 or 1, and still more preferably 0. The lower limit of the sum of p1, p2, p3 and p4 is preferably 1. The upper limit of the sum of p1, p2, p3 and p4 is preferably 34, more preferably 18, still more preferably 8, particularly preferably 4, still particularly preferably 3, and most preferably 2.

The alkyl group which may be represented by R⁵ to R⁸ in the above formula (2) is exemplified by an alkyl group having 1 to 20 carbon atoms, and the like, and examples thereof include a methyl group, an ethyl group, a propyl group, a butyl group, a pentyl group, a hexyl group, an octyl group, a decyl group, and the like.

The alkoxy group which may be represented by R⁵ to R⁸ is exemplified by an alkoxy group having 1 to 20 carbon atoms, and the like, and examples thereof include a methoxy group, an ethoxy group, a propoxy group, a butoxy group, a pentyloxy group, a hexyloxy group, an octyloxy group, a decyloxy group, and the like.

The monovalent carbon-carbon triple bond-containing group which may be represented by R⁵ to R⁸ is exemplified by the monovalent groups among the groups exemplified in connection with the specific group (A), groups obtained by incorporating an oxygen atom into the end on the atomic bonding side of the monovalent groups, and the like.

The carbon-carbon double bond-containing group which may be represented by R⁵ to R⁸ is exemplified by groups similar to the groups exemplified in connection with the carbon-carbon double bond-containing group which may be represented by R¹ to R⁴ in the above formula (1), groups obtained by incorporating an oxygen atom into the end on the atomic bonding side of the above-mentioned groups, and the like.

In the above formula (2), b1 and b3 are each independently preferably 0 or 1, and more preferably 0; b2 and b4 are each independently preferably an integer of 0 to 2, more preferably 0 or 1, and still more preferably 0; q1 and q3 are each independently preferably 0 or 1, and more preferably 1; and q2 and q4 are each independently preferably an integer of 0 to 2, more preferably 0 or 1, and still more preferably 0. The lower limit of the sum of q1, q2, q3 and q4 is preferably 1. The upper limit of the sum of q1, q2, q3 and q4 is preferably 10, more preferably 8, still more preferably 6, particularly preferably 4, still particularly preferably 3, and most preferably 2.

R⁵ to R⁸ each independently represent preferably an alkyl group, a hydroxy group or a monovalent carbon-carbon triple bond-containing group, more preferably a hydroxy group or a monovalent carbon-carbon triple bond-containing group, still more preferably a hydroxy group or an alkynyloxy group, and particularly preferably a hydroxy group or a propargyloxy group.

Examples of the partial structure (1) include partial structures represented by the following formulae (1-1) to (1-6) (hereinafter, may be also referred to as “partial structures (I-1) to (I-6)”), and the like. Examples of the partial structure (II) include partial structures represented by the following formulae (2-1) to (2-6) (hereinafter, may be also referred to as “partial structures (II-1) to (II-6)”), and the like.

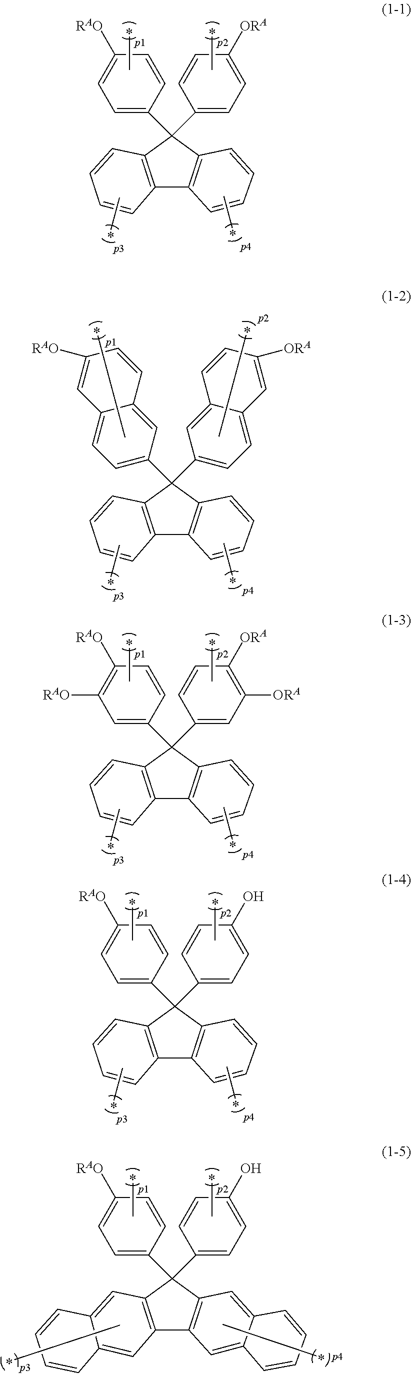

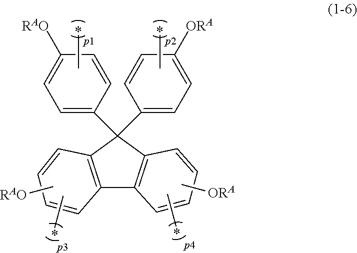

In the above formulae (1-1) to (1-6), R^{A} represents a monovalent specific group (A); R^{B} represents a monovalent carbon-carbon double bond-containing group; p1 to p4 are as defined in the above formula (1); and * denotes a binding site to a moiety other than the partial structures (1-1) to (1-6) in the compound (A).

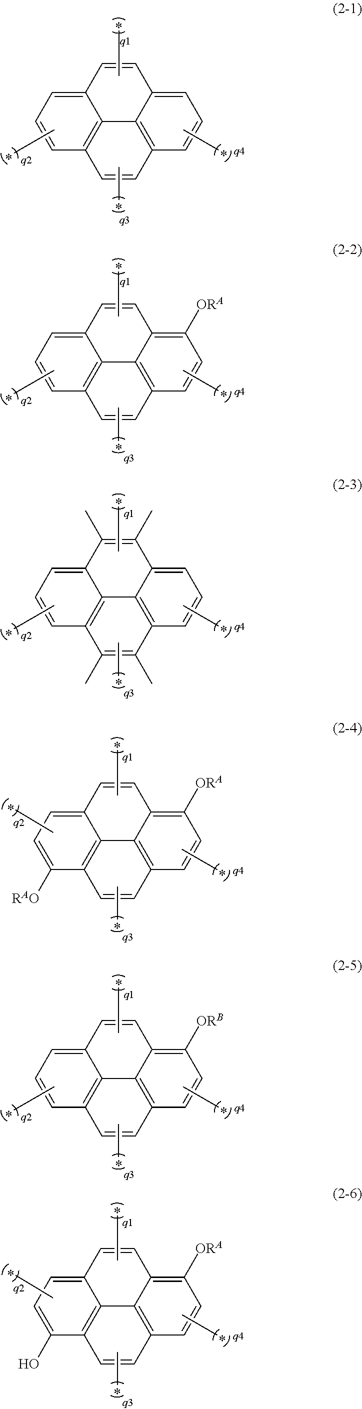

In the above formulae (2-1) to (2-6), R^{A} represents the monovalent specific group (A); R^{B} represents the monovalent carbon-carbon double bond-containing group; q1 to q4 are as defined in the above formula (2); and * denotes a binding site to a moiety other than the partial structures (II-1) to (II-6) in the compound (A).

As the partial structure (I), the partial structures (I-1), (I-2) and (I-4) are preferred, and the partial structures (I-1) and (I-2) are more preferred. As the partial structure (II), the partial structures (II-1) and (II-2) are preferred, and the partial structure (II-1) is more preferred.

The compound (A) has, as the partial structure (A), preferably at least one of the partial structure (I) and the partial structure (II), more preferably the partial structure (I), and still more preferably the partial structure (I) and the partial structure (II). When the compound (A) has the partial structure(s) described above, the solubility of the compound (A) in a solvent may be further increased, and consequently the filling performances of the resist underlayer film may be more improved.

When the compound (A) has the partial structure (I), the lower limit of the proportion of the partial structure (I) with respect to the entirety of the partial structures (A) constituting the compound (A) is preferably 10 mol %, more preferably 30 mol %, and still more preferably 50 mol %. The upper limit of the proportion of the partial structure (T) is preferably 100 mol %, more preferably 95 mol %, and still more preferably 75 mol %. When the proportion of the partial structure (I) falls within the above range, the solubility of the compound (A) in a solvent may be further increased, and consequently the heat resistance and the filling performances of the resist underlayer film can be both attained at a higher level.

When the compound (A) has the partial structure (II), the lower limit of the proportion of the partial structure (II) with respect to the entirety of the partial structures (A) constituting the compound (A) is preferably 10 mol %, more preferably 20 mol %, and still more preferably 30 mol %. The upper limit of the proportion of the partial structure (II) is preferably 100 mol %, more preferably 80 mol %, and still more preferably 50 mol %. When the proportion of the partial structure (II) falls within the above range, the percentage content of the polycyclic structure in the compound (A) can be increased, and consequently the heat resistance and the filling performances of the resist underlayer film can be both attained at a higher level. The compound (A) may have one, or two or more types of the partial structure (A).

### Other Partial Structure

Other partial structure than the partial structure (A) (hereinafter, may be also referred to as “other partial structure”) in the compound (A) is exemplified by partial structures represented by the following formulae (3) to (6), a partial structure not having an aromatic ring, and the like.

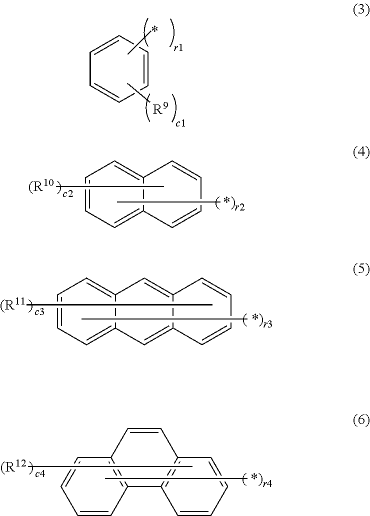

In the above formula (3), R⁹ represents an alkyl group, a hydroxy group, a monovalent carbon-carbon triple bond-containing group or a monovalent carbon-carbon double bond-containing group; c1 is an integer of 0 to 5, wherein in a case where c1 is no less than 2, a plurality of R⁹s may be identical or different; and r1 is an integer of 1 to 6, wherein the sum of c1 and r1 is no greater than 6.

In the above formula (4), R¹⁰ represents an alkyl group, a hydroxy group, a monovalent carbon-carbon triple bond-containing group or a monovalent carbon-carbon double bond-containing group; c2 is an integer of 0 to 7, wherein in a case where c2 is no less than 2, a plurality of R¹⁰s may be identical or different; and r2 is an integer of 1 to 8, wherein the sum of c2 and r2 is no greater than 8.

In the above formula (5), R¹¹ represents an alkyl group, a hydroxy group, a monovalent carbon-carbon triple bond-containing group or a monovalent carbon-carbon double bond-containing group; c3 is an integer of 0 to 9, wherein in a case c3 is no less than 2, a plurality of R¹¹s may be identical or different; and r3 is an integer of 1 to 10, wherein the sum of c3 and r3 is no greater than 10.

In the above formula (6), R¹² represents an alkyl group, a hydroxy group, a monovalent carbon-carbon triple bond-containing group or a monovalent carbon-carbon double bond-containing group; c4 is an integer of 0 to 9, wherein in a case where c4 is no less than 2, a plurality of R¹²s may be identical or different; and r4 is an integer of 1 to 10, wherein the sum of c4 and r4 is no greater than 10.

R⁹ in the above formula (3) represents preferably a monovalent carbon-carbon triple bond-containing group or a hydroxy group, more preferably a monovalent carbon-carbon triple bond-containing group, still more preferably an alkynyloxy group, and particularly preferably a propargyloxy group. Preferably, c1 is 1. Preferably, r1 is 1 to 3, and more preferably 2.

R¹⁰ in the above formula (4) represents preferably a monovalent carbon-carbon triple bond-containing group or a hydroxy group, more preferably a monovalent carbon-carbon triple bond-containing group, still more preferably an alkynyloxy group, and particularly preferably a propargyloxy group. Preferably, c2 is 1. Preferably, r2 is 1 to 3, and more preferably 2.

R¹¹ in the above formula (5) represents preferably a monovalent carbon-carbon triple bond-containing group or a hydroxy group, more preferably a monovalent carbon-carbon triple bond-containing group, still more preferably an alkynyloxy group, and particularly preferably a propargyloxy group. Preferably, c3 is 0 or 1, and more preferably 0. Preferably, r3 is 1 to 3, and more preferably 2.

R′² in the above formula (6) represents preferably a monovalent carbon-carbon triple bond-containing group or a hydroxy group, more preferably a monovalent carbon-carbon triple bond-containing group, still more preferably an alkynyloxy group, and particularly preferably a propargyloxy group. Preferably, c4 is 0 or 1, and more preferably 0. Preferably, r4 is 1 to 3, and more preferably 2.

The partial structure not having an aromatic ring is exemplified by a partial structure constituted with a substituted or unsubstituted chain hydrocarbon group, a partial structure constituted with a substituted or unsubstituted alicyclic hydrocarbon group, and the like.

The lower limit of the proportion of the partial structure (A) with respect to the entirety of the partial structures constituting the compound (A) is preferably 40 mol %, more preferably 50 mol %, still more preferably 60 mol %, and particularly preferably 70 mol %. The upper limit of the proportion of the partial structure (A) is preferably 100 mol %, more preferably 95 mol %, and still more preferably 90 mol %. When the proportion of the partial structure (A) falls within the above range, the heat resistance and the filling performances of the resist underlayer film may be further improved.

When the compound (A) has the other partial structure, the lower limit of the proportion of the other partial structure with respect to the entirety of the partial structures constituting the compound (A) is preferably 1 mol %, more preferably 5 mol %, and still more preferably 10 mol %. The upper limit of the proportion of the other partial structure is preferably 60 mol %, more preferably 50 mol %, still more preferably 40 mol %, and particularly preferably 30 mol %. When the proportion of the other partial structure falls within the above range, the solvent resistance, the etching resistance, the heat resistance and the filling performances of the resist underlayer film may be further improved.

### Linking Group

When the compound (A) has a plurality of the partial structures, the partial structures may be linked to one another through the linking group (a). In addition, when the compound (A) has a plurality of the partial structures (A), the plurality of the partial structures (A) may be linked to one another through the linking group (a).

The linking group (a) is exemplified by a linking group derived from an aldehyde, and the like. When the linking group is derived from a compound having one aldehyde group, the linking group typically has a structure of —CHR—, wherein R represents a monovalent hydrocarbon group. R represents preferably a hydrogen atom or an aryl group, more preferably a hydrogen atom or a pyrenyl group, and still more preferably a hydrogen atom. A linking group derived from formaldehyde is typically —CH₂—.

In regard to the aldehyde, examples of the compound having one aldehyde group include formaldehyde, acetaldehyde, propionaldehyde, butyraldehyde, benzaldehyde, naphthoaldehyde, formylpyrene, and the like.

Examples of a compound having two or more aldehyde groups include 1,4-phenylenedialdehyde, 4,4′-biphenylenedialdehyde, and the like.

When the compound (A) has the linking group (a), the lower limit of the amount of the linking group (a) with respect to 1 mol of the entirety of the partial structures constituting the compound (A) is preferably 0.1 mol, more preferably 0.3 mol, and still more preferably 0.5 mol. The upper limit of the proportion of the linking group (a) with respect to 1 mol of the entirety of the partial structures constituting the compound (A) is preferably 3 mol, more preferably 2 mol, and still more preferably 1.5 mol. When the proportion of the linking group (a) falls within the above range, the crosslinking density of the compound (A) by the linking group (a) may be more appropriately adjusted, and consequently the solvent resistance, the etching resistance, the heat resistance and the filling performances of the resist underlayer film may be more improved.

Examples of the compound (A) include compounds having structures represented by the following formulae (A-1) to (A-11) (hereinafter, may be also referred to as “compounds (A1) to (A11)”), and the like.

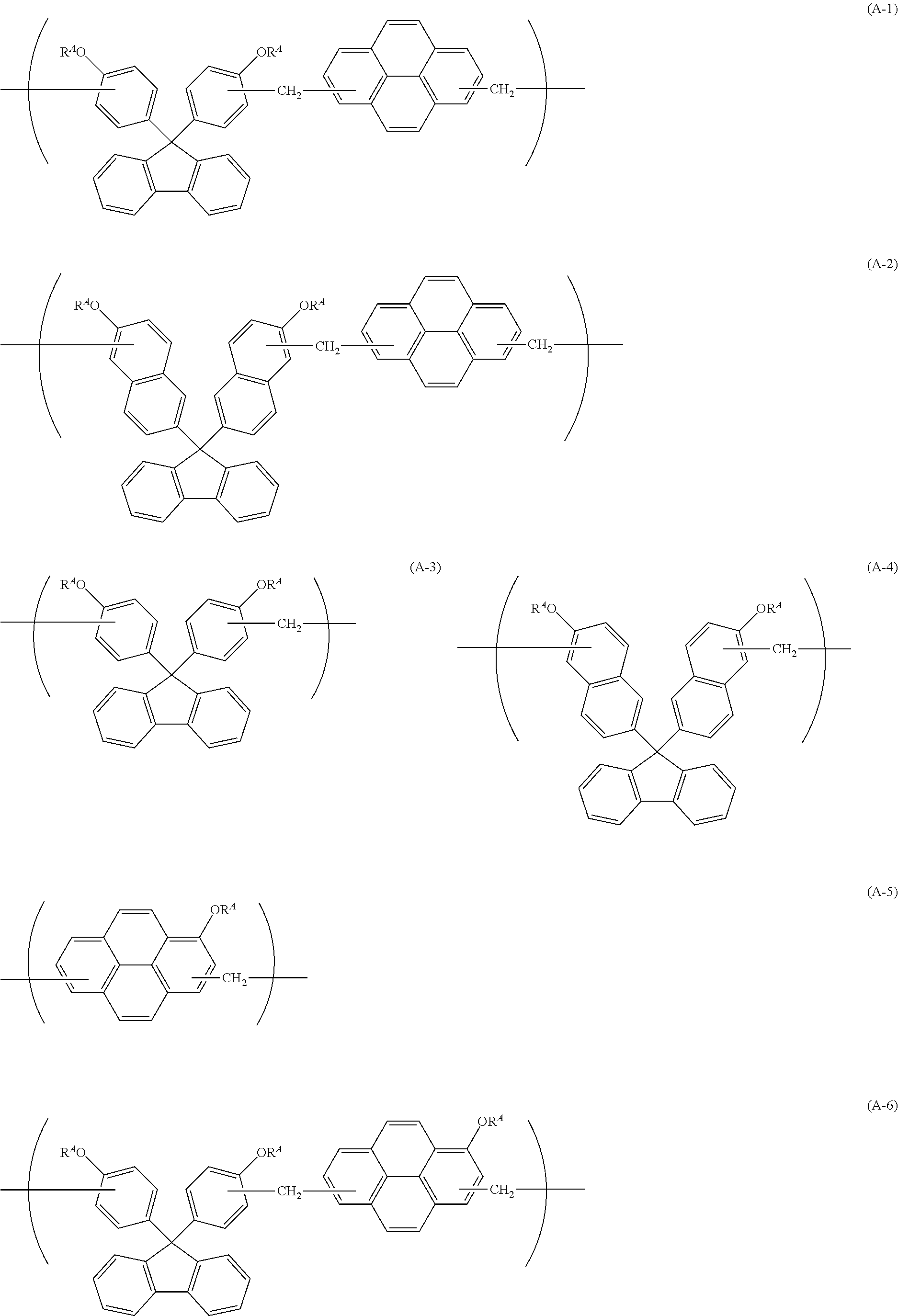

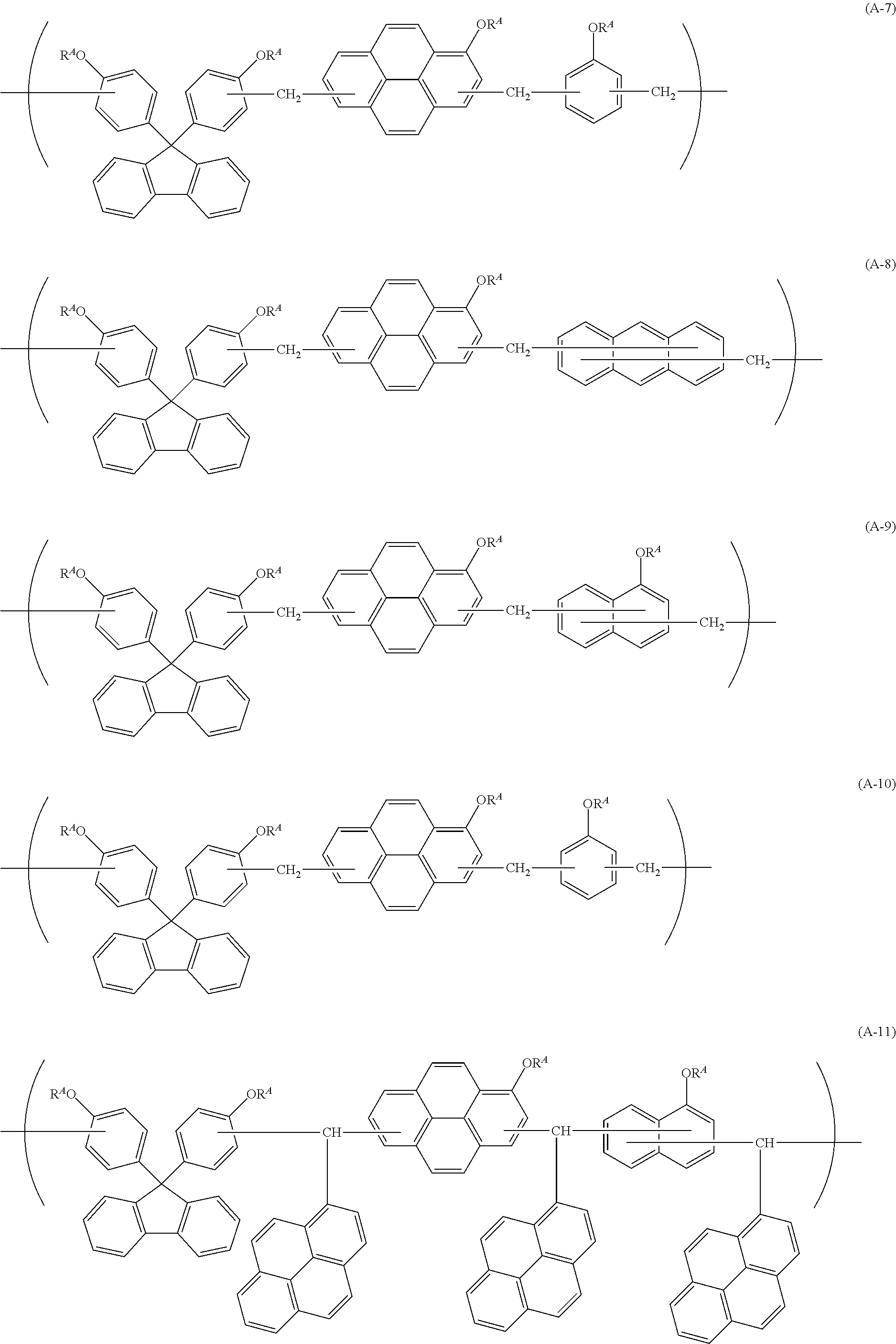

In the above formulae (A-1) to (A-11), R^{A} represents a monovalent specific group (A).

Of these, as the compound (A), the compounds (A1) to (A5) and (A7) to (A11) are preferred, the compounds (A1), (A3) to (A5) and (A7) to (A11) are more preferred, and the compounds (A1) and (A7) to (A11) are still more preferred.

The lower limit of the content of the compound (A) with respect to the total solid content (all components except for the solvent) in the composition for resist underlayer film formation is preferably 70% by mass, more preferably 80% by mass, and still more preferably 85% by mass.

### Synthesis Method of Compound (A)

The compound (A) can be synthesized by a well-known method. When a polymer obtained by crosslinking a compound that gives the partial structure (A) with an aldehyde is to be synthesized as the compound (A), a precursor compound such as e.g. a phenolic hydroxyl group-containing compound represented by the following formula (1-m) and a compound represented by the following formula (2-in) is first reacted with the aldehyde in a solvent such as propylene glycol monomethyl ether acetate in the presence of an acid to give a polymer having a phenolic hydroxyl group. Next, the resulting polymer is reacted with a compound that gives the specific group (A), such as propargyl bromide, in a solvent such as N,N-dimethylacetamide in the presence of a base, whereby the compound (A) can be synthesized. One, or two or more types of the precursor compound may be used, and the proportion(s) of the precursor(s) used may be appropriately selected in accordance with desired performances of the resist underlayer film, etc. Also, the ratio of the precursor compound to the aldehyde may be appropriately selected in accordance with desired performances of the resist underlayer film, etc.

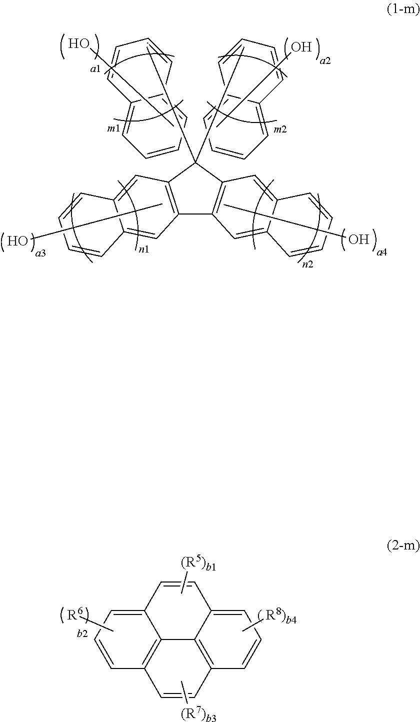

In the above formula (1-m), m1, m2, n1, n2 and a1 to a4 are as defined in the above formula (1).

In the above formula (2-m), R⁵ to R⁸ and b1 to b4 are as defined in the above formula (2).

Examples of the aldehyde include: compounds having one aldehyde group, such as formaldehyde (paraformaldehyde), acetaldehyde (paraldehyde), propionaldehyde, butyraldehyde, benzaldehyde, naphthoaldehyde and formylpyrene; compounds having two or more aldehyde groups, such as 1,4-phenylenedialdehyde and 4,4′-biphenylenedialdehyde; and the like. Of these, in light of a further improvement of the solvent resistance, the etching resistance, the heat resistance and the filling performances of the resist underlayer film due to the compound (A) having a more appropriate cross-linked structure, the compounds having one aldehyde group are preferred, formaldehyde and formylpyrene are more preferred, and formaldehyde is still more preferred.

Examples of the acid include sulfonic acids such as p-toluenesulfonic acid and benzenesulfonic acid; inorganic acids such as sulfuric acid, hydrochloric acid and nitric acid; and the like. Of these, the sulfonic acids are preferred, and p-toluenesulfonic acid is more preferred.

The lower limit of the amount of the acid with respect to 100 mol of the aldehyde is preferably 0.1 mol, and more preferably 0.5 mol. The upper limit of the amount of the acid is preferably 20 mol, and more preferably 10 mol.

The lower limit of the reaction temperature in the synthesis reaction of the polymer having a phenolic hydroxyl group is preferably 60° C., and more preferably 80° C. The upper limit of the reaction temperature is preferably 150° C., and more preferably 120° C. The lower limit of the reaction time period in the reaction is preferably 1 hour, and more preferably 4 hrs. The upper limit of the reaction time period is preferably 24 hrs, and more preferably 12 hrs.

Examples of the base include: alkali metal carbonates such as potassium carbonate and sodium carbonate; alkali metal hydrogencarbonates such as lithium hydrogencarbonate, sodium hydrogencarbonate and potassium hydrogencarbonate; alkali metal hydroxides such as potassium hydroxide and sodium hydroxide; alkali metal hydrides such as lithium hydride, sodium hydride and potassium hydride; and the like. Of these, the alkali metal carbonates are preferred, and potassium carbonate is more preferred.

The lower limit of the amount of the base with respect to 1 mol of the compound that gives the specific group (A) is preferably 0.1 mol, more preferably 0.5 mol, and still more preferably 0.8 mol. The upper limit of the amount of the base is preferably 3 mol, more preferably 2 mol, and still more preferably 1.5 mol.

The lower limit of the reaction temperature in a reaction in which the compound that gives the specific group (A) is reacted to obtain the compound (A) is preferably 50° C., and more preferably 60° C. The upper limit of the reaction temperature is preferably 130° C., and more preferably 100° C. The lower limit of the reaction time period of the reaction is preferably 1 hour, and more preferably 4 hrs. The upper limit of the reaction time period is preferably 24 hrs, and more preferably 12 hrs.

The synthesized compound (A) may be purified from the reaction mixture through liquid separation operation, reprecipitation, recrystallization, distillation, and/or the like. Compounds (A) other than those described above can be synthesized in a similar manner.

The lower limit of the molecular weight of the compound (A) is preferably 250, more preferably 1,000, still more preferably 2,000, and particularly preferably 3,000. The upper limit of the molecular weight is preferably 10,000, more preferably 7,000, still more preferably 6,000, and particularly preferably 5,000.

When the compound (A) is a polymer, the lower limit of the weight average molecular weight (Mw) of the compound (A) is preferably 1,000, more preferably 2,000, still more preferably 3,000, and particularly preferably 4,000. The upper limit of the Mw is preferably 15,000, more preferably 10,000, still more preferably 8,500, and particularly preferably 7,000.

When the molecular weight of the compound (A) falls within the above range, the solvent resistance, the etching resistance, the heat resistance and the filling performances of the resist underlayer film may be further improved.

When the compound (A) is a polymer, the upper limit of the ratio (Mw/Mn ratio) of the Mw to the number average molecular weight (Mn) of the compound (A) is preferably 5, more preferably 3, still more preferably 2, and particularly preferably 1.8. The lower limit of the Mw/Mn ratio is typically 1, and preferably 1.2. When the Mw/Mn ratio of the compound (A) falls within the above range, the filling performances of the resist underlayer film may be more improved.

### (B) Solvent

The composition for resist underlayer film formation contains the solvent (B). The solvent (B) is not particularly limited as long as it can dissolve or disperse the compound (A), and the optional component contained as needed.

The solvent (B) is exemplified by an alcohol solvent, a ketone solvent, an amide solvent, an ether solvent, an ester solvent, and the like. The solvent (B) may be used either alone of one type, or in combination of two or more types thereof.

Examples of the alcohol solvent include:

monohydric alcohol solvents such as methanol, ethanol, n-propanol, iso-propanol, n-butanol, iso-butanol, sec-butanol, t-butanol, n-pentanol, iso-pentanol, sec-pentanol and t-pentanol;

polyhydric alcohol solvents such as ethylene glycol, 1,2-propylene glycol, 1,3-butylene glycol, 2,4-pentanediol, 2-methyl-2,4-pentanediol, 2,5-hexanediol and 2,4-heptanediol; and the like.

Examples of the ketone solvent include:

aliphatic ketone solvents such as acetone, methyl ethyl ketone, methyl n-propyl ketone, methyl n-butyl ketone, diethyl ketone, methyl iso-butyl ketone, methyl n-pentyl ketone, ethyl n-butyl ketone, methyl n-hexyl ketone, di-iso-butyl ketone and trimethylnonanone;

cyclic ketone solvents such as cyclopentanone, cyclohexanone, cycloheptanone, cyclooctanone and methylcyclohexanone;

2,4-pentanedione, acetonylacetone, diacetone alcohol, acetophenone, and methyl n-amyl ketone; and the like.

Examples of the amide solvent include:

cyclic amide solvents such as 1,3-dimethyl-2-imidazolidinone and N-methyl-2-pyrrolidone;

chain amide solvents such as formamide, N-methylformamide, N,N-dimethylformamide, N,N-diethylformamide, acetamide, N-methylacetamide, N,N-dimethylacetamide and N-methylpropionamide; and the like.

Examples of the ether solvent include:

polyhydric alcohol partial ether solvents such as ethylene glycol monomethyl ether, ethylene glycol monoethyl ether and ethylene glycol dimethyl ether;

polyhydric alcohol partial ether acetate solvents such as ethylene glycol monomethyl ether acetate, ethylene glycol monoethyl ether acetate, propylene glycol monomethyl ether acetate (PGMEA) and propylene glycol monoethyl ether acetate;
dialiphatic ether solvents such as diethyl ether, dipropyl ether, dibutyl ether, butyl methyl ether, butyl ethyl ether and diisoamyl ether;

aliphatic-aromatic ether solvents such as anisole and phenyl ethyl ether;

cyclic ether solvents such as tetrahydrofuran, tetrahydropyran and dioxane; and the like.

Examples of the ester solvent include:

carboxylic acid ester solvents such as methyl lactate, ethyl lactate, methyl acetate, ethyl acetate, n-propyl acetate, iso-propyl acetate, n-butyl acetate, iso-butyl acetate, sec-butyl acetate, n-pentyl acetate, sec-pentyl acetate, 3-m ethoxybutyl acetate, methylpentyl acetate, 2-ethylbutyl acetate, 2-ethylhexyl acetate, benzyl acetate, cyclohexyl acetate, in ethyl cyclohexyl acetate, n-nonyl acetate, methyl acetoacetate and ethyl acetoacetate;

lactone solvents such as γ-butyrolactone and γ-valerolactone;

carbonic acid ester solvents such as diethyl carbonate and propylene carbonate; and the like.

Of these, the ether solvent, the ketone solvent and the ester solvent are preferred, and the ether solvent is more preferred. The ether solvent is preferably the polyhydric alcohol partial ether acetate solvent or the dialiphatic ether solvent, more preferably the polyhydric alcohol partial ether acetate solvent, still more preferably propylene glycol monoalkyl ether acetate, and particularly preferably PGMEA. The ketone solvent is preferably the cyclic ketone solvent, and more preferably cyclohexanone or cyclopentanone. The ester solvent is preferably the carboxylic acid ester solvent or the lactone solvent, more preferably the carboxylic acid ester solvent, and still more preferably ethyl lactate.

The polyhydric alcohol partial ether acetate solvent, more specifically the propylene glycol monoalkyl ether acetate, in particular PGMEA, is preferred since when PGMEA is contained in the solvent (B), application properties of the composition for resist underlayer film formation to a substrate such as a silicon wafer may be improved. The compound (A) contained in the composition for resist underlayer film formation exhibits more superior solubility in PGMEA or the like; accordingly, when the solvent (B) contains the polyhydric alcohol partial ether acetate solvent, the composition for resist underlayer film formation may exhibit superior application properties, and consequently the filling performances of the resist underlayer film may be more improved. The lower limit of the percentage content of the polyhydric alcohol partial ether acetate solvent in the solvent (B) is preferably 20% by mass, more preferably 60% by mass, still more preferably 90% by mass, and particularly preferably 100% by mass.

### (C) Acid Generating Agent

The acid generating agent (C) is a component that generates an acid by an action of heat and/or light and facilitates the crosslinking of molecules of the compound (A). When the composition for resist underlayer film formation contains the acid generating agent (C), the crosslinking reaction of molecules of the compound (A) is facilitated and the hardness of the formed film may be further increased. The acid generating agent (C) may be used either alone of one type, or in combination of two or more types thereof.

The acid generating agent (C) is exemplified by an onium salt compound, an N-sulfonyloxyimide compound, and the like.

The onium salt compound is exemplified by a sulfonium salt, a tetrahydrothiophenium salt, an iodonium salt, and the like.

Examples of the sulfonium salt include triphenylsulfonium trifluoromethanesulfonate, triphenylsulfonium nonafluoro-n-butanesulfonate, triphenylsulfonium perfluoro-n-octanesulfonate, triphenylsulfonium 2-bicyclo[2.2.1]hept-2-yl-1,1,2,2-tetrafluoroethanesulfonate, 4-cyclohexylphenyldiphenylsulfonium trifluoromethanesulfonate, 4-cyclohexylphenyldiphenylsulfonium nonafluoro-n-butanesulfonate, 4-cyclohexylphenyldiphenylsulfonium perfluoro-n-octanesulfonate, 4-cyclohexylphenyldiphenylsulfonium 2-bicyclo[2.2.1]hept-2-yl-1,1,2,2-tetrafluoroethanesulfonate, 4-methanesulfonylphenyldiphenylsulfonium trifluoromethanesulfonate, 4-methanesulfonylphenyldiphenylsulfonium nonafluoro-n-butanesulfonate, 4-methanesulfonylphenyldiphenylsulfonium perfluoro-n-octanesulfonate, 4-methanesulfonylphenyldiphenylsulfonium 2-bicyclo[2.2.1]hept-2-yl-1,1,2,2-tetrafluoroethanesulfonate, and the like.

Examples of the tetrahydrothiophenium salt include 1-(4-n-butoxynaphthalen-1-yl)tetrahydrothiophenium trifluoromethanesulfonate, 1-(4-n-butoxynaphthalen-1-yl)tetrahydrothiophenium nonafluoro-n-butanesulfonate, 1-(4-n-butoxynaphthalen-1-yl)tetrahydrothiophenium perfluoro-n-octanesulfonate, 1-(4-n-butoxynaphthalen-1-yl)tetrahydrothiophenium 2-bicyclo[2.2.1]hept-2-yl-1,1,2,2-tetrafluoroethanesulfonate, 1-(6-n-butoxynaphthalen-2-yl)tetrahydrothiophenium trifluoromethanesulfonate, 1-(6-n-butoxynaphthalen-2-yl)tetrahydrothiophenium nonafluoro-n-butanesulfonate, 1-(6-n-butoxynaphthalen-2-yl)tetrahydrothiophenium perfluoro-n-octanesulfonate, 1-(6-n-butoxynaphthalen-2-yl)tetrahydrothiophenium 2-bicyclo[2.2.1]hept-2-yl-1,1,2,2-tetrafluoroethanesulfonate, 1-(3,5-dimethyl-4-hydroxyphenyl)tetrahydrothiophenium trifluoromethanesulfonate, 1-(3,5-dimethyl-4-hydroxyphenyl)tetrahydrothiophenium nonafluoro-n-butanesulfonate, 1-(3,5-dimethyl-4-hydroxyphenyl)tetrahydrothiophenium perfluoro-n-octanesulfonate, 1-(3,5-dimethyl-4-hydroxyphenyl)tetrahydrothiophenium 2-bicyclo[2.2.1]hept-2-yl-1,1,2,2-tetrafluoroethanesulfonate, and the like.

Examples of the iodonium salt include diphenyliodonium trifluoromethanesulfonate, diphenyliodonium nonafluoro-n-butanesulfonate, diphenyliodonium perfluoro-n-octanesulfonate, diphenyliodonium 2-bicyclo[2.2.1]hept-2-yl-1,1,2,2-tetrafluoroethanesulfonate, bis(4-t-butylphenyl)iodonium trifluoromethanesulfonate, bis(4-t-butylphenyl)iodonium nonafluoro-n-butanesulfonate, bis(4-t-butylphenyl)iodonium perfluoro-n-octanesulfonate, bis(4-t-butylphenyl)iodonium 2-bicyclo[2.2.1]hept-2-yl-1,1,2,2-tetrafluoroethanesulfonate, and the like.

Examples of the N-sulfonyloxyimide compound include N-(trifluoromethanesulfonyloxy)bicyclo[2.2.1]hept-5-ene-2,3-dicarboxyimide, N-(nonafluoro-n-butanesulfonyloxy)bicyclo[2.2.1]hept-5-ene-2,3-dicarboxyimide, N-(perfluoro-n-octanesulfonyloxy)bicyclo[2.2.1]hept-5-ene-2,3-dicarboxyimide, N-(2-bicyclo[2.2.1]hept-2-yl-1,1,2,2-tetrafluoroethanesulfonyloxy)bicyclo[2.2.1]hept-5-ene-2,3-dicarboxyimide, and the like.

Of these, the acid generating agent (C) is preferably the onium salt compound, more preferably the iodonium salt, and still more preferably bis(4-t-butylphenyl)iodonium nonafluoro-n-butanesulfonate.

When the composition for resist underlayer film formation contains the acid generating agent (C), the lower limit of the content of the acid generating agent (C) with respect to 100 parts by mass of the compound (A) is preferably 0.1 parts by mass, more preferably 1 part by mass, and still more preferably 3 parts by mass. The upper limit of the content of the acid generating agent (C) with respect to 100 parts by mass of the compound (A) is preferably 20 parts by mass, more preferably 15 parts by mass, and still more preferably 10 parts by mass. When the content of the acid generating agent (C) falls within the above range, the crosslinking reaction of molecules of the compound (A) may be facilitated more effectively.

### Other Optional Component

Other optional component which may be contained in the composition for resist underlayer film formation is exemplified by a crosslinking agent, a surfactant, an adhesion aid, and the like.

### Crosslinking Agent

The crosslinking agent is a component that forms a crosslinking bond between components, such as the compound (A) in the composition for resist underlayer film formation, by an action of heat and/or an acid. When the composition for resist underlayer film formation contains the crosslinking agent, the hardness of the formed film can be increased. The crosslinking agent may be used either alone of one type, or in combination of two or more types thereof.

The crosslinking agent is exemplified by a polyfunctional (meth)acrylate compound, an epoxy compound, a hydroxymethyl group-substituted phenol compound, an alkoxyalkyl group-containing phenol compound, a compound having an alkoxyalkylated amino group, a random copolymer of an acenaphthylene with hydroxymethylacenaphthylene which is represented by the following formula (7-P), compounds represented by the following formulae (7-1) to (7-12), and the like.

Examples of the polyfunctional (meth)acrylate compound include trimethylolpropane tri(meth)acrylate, ditrimethylolpropane tetra(meth)acrylate, pentaerythritol tri(meth)acrylate, pentaerythritol tetra(meth)acrylate, dipentaerythritol penta(meth)acrylate, dipentaerythritol hexa(meth)acrylate, glycerin tri(meth)acrylate, tris(2-hydroxyethyl)isocyanurate tri(meth)acrylate, ethylene glycol di(meth)acrylate, 1,3-butanediol di(meth)acrylate, 1,4-butanediol di(meth)acrylate, 1,6-hexanediol di(meth)acrylate, neopentyl glycol di(meth)acrylate, di ethylene glycol di(meth)acrylate, tri ethylene glycol di(meth)acrylate, dipropyl en e glycol di(meth)acrylate, bis(2-hydroxyethyl)isocyanurate di(meth)acrylate, and the like.

Examples of the epoxy compound include novolak epoxy resins, bisphenol epoxy resins, alicyclic epoxy resins, aliphatic epoxy resins, and the like.

Examples of the hydroxymethyl group-substituted phenol compound include 2-hydroxymethyl-4,6-dimethylphenol, 1,3,5-trihydroxymethylbenzene, 3,5-dihydroxymethyl-4-methoxytoluene (i.e., 2,6-bis(hydroxymethyl)-p-cresol), and the like.

Examples of the alkoxyalkyl group-containing phenol compound include methoxymethyl group-containing phenol compounds, ethoxymethyl group-containing phenol compounds, and the like.

Examples of the compound having an alkoxyalkylated amino group include nitrogen-containing compounds having a plurality of active methylol groups in a molecule thereof, wherein the hydrogen atom of the hydroxyl group of at least one of the methylol groups is substituted with an alkyl group such as a methyl group or a butyl group, and the like; examples thereof include (poly)methylolated melamines, (poly)methylolated glycolurils, (poly)methylolated benzoguanamines, (poly)methylolated ureas, and the like. It is to be noted that a mixture constituted with a plurality of substituted compounds described above may be used as the compounds having an alkoxyalkylated amino group, and the compound having an alkoxyalkylated amino group may contain an oligomer component formed through partial self-condensation thereof.

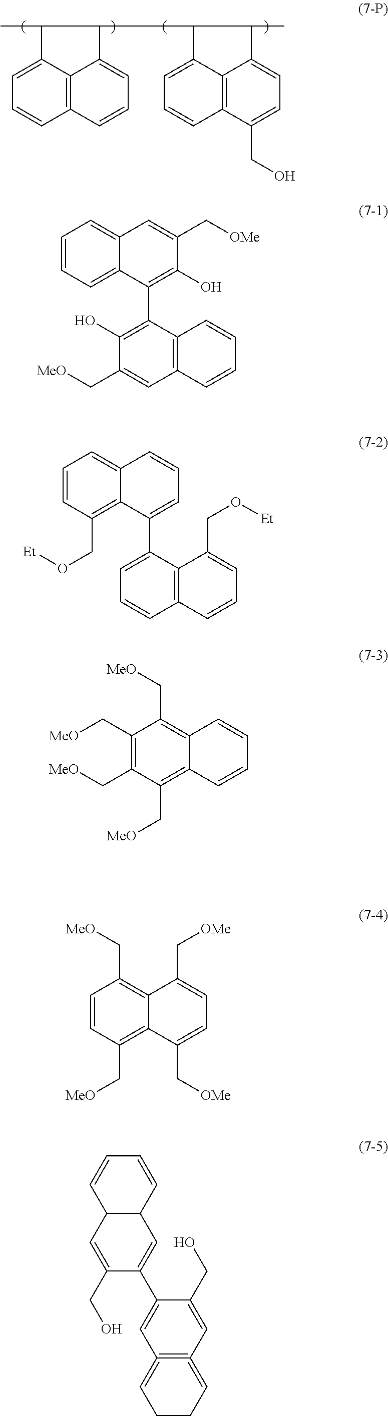

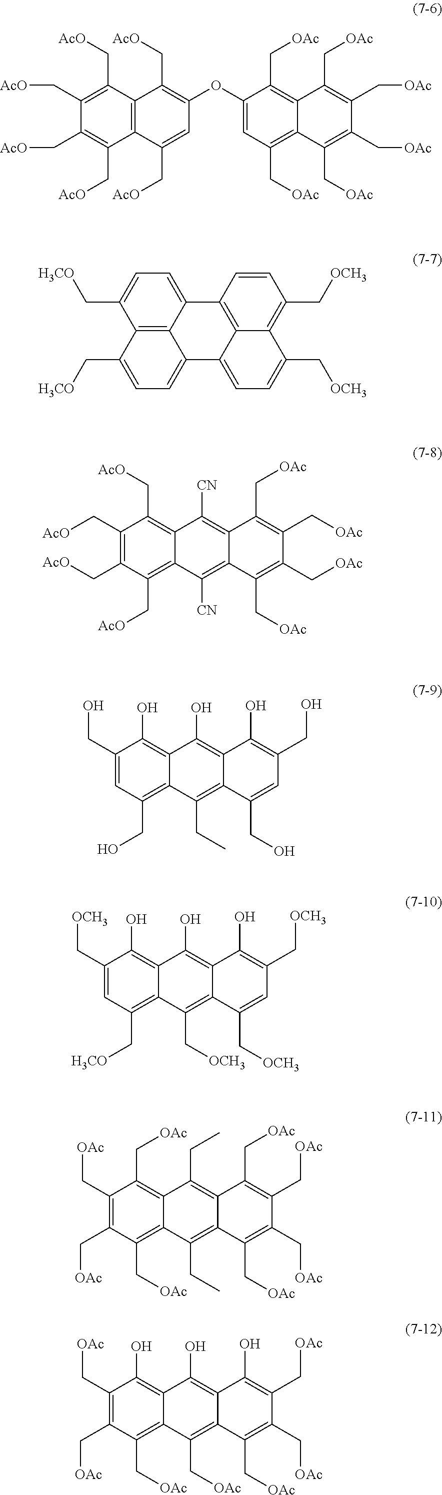

In the above formulae (7-6), (7-8), (7-11) and (7-12), Ac represents an acetyl group.

It is to be noted that the compounds represented by the above formulae (7-1) to (7-12) each may be synthesized with reference to the following documents.

The compound represented by the formula (7-1):

Guo, Qun-Sheng; Lu, Yong-Na; Liu, Bing; Xiao, Jian; and Li, Jin-Shan, Journal of Organometallic Chemistry, 2006, vol. 691, #6, p. 1282-1287.

The compound represented by the formula (7-2):

Badar, Y et al., Journal of the Chemical Society, 1965, p. 1412-1418.

The compound represented by the formula (7-3):

Hsieh, Jen-Chieh; Cheng, Chien-Hong, Chemical Communications (Cambridge, United Kingdom), 2008, #26, p. 2992-2994.

The compound represented by the formula (7-4): Japanese Unexamined Patent Application, Publication No. H5-238990.

The compound represented by the formula (7-5):

Bacon, R. G. R.; Bankhead, R., Journal of the Chemical Society, 1963, p. 839-845.

The compounds represented by the formulae (7-6), (7-8), (7-11) and (7-12):

Macromolecules, 2010, vol. 43, p. 2832-2839.

The compounds represented by the formulae (7-7), (7-9) and (7-10):

Polymer Journal, 2008, vol. 40, No. 7, p. 645-650; and Journal of Polymer Science: Part A, Polymer Chemistry, vol. 46, p. 4949-4958.

Among these crosslinking agents, the methoxymethyl group-containing phenol compound, the compound having an alkoxyalkylated amino group, and the random copolymer of acenaphthylene with hydroxymethylacenaphthylene are preferred, the compound having an alkoxyalkylated amino group is more preferred, and 1,3,4,6-tetra(methoxymethyl)glycoluril is still more preferred.

When the composition for resist underlayer film formation contains the crosslinking agent, the lower limit of the content of the crosslinking agent with respect to 100 parts by mass of the compound (A) is preferably 0.1 parts by mass, more preferably 0.5 parts by mass, still more preferably 1 part by mass, and particularly preferably 3 parts by mass. The upper limit of the content of the crosslinking agent with respect to 100 parts by mass of the compound (A) is preferably 100 parts by mass, more preferably 50 parts by mass, still more preferably 30 parts by mass, and particularly preferably 20 parts by mass. When the content of the crosslinking agent falls within the above range, the crosslinking reaction of molecules of the compound (A) may be allowed to occur more effectively.

### Surfactant

When the composition for resist underlayer film formation contains the surfactant, application properties thereof can be improved, and consequently uniformity of the surface of the formed film may be improved and occurrence of the unevenness of coating can be inhibited. The surfactant may be used either alone of one type, or in combination of two or more types thereof.

Examples of the surfactant include nonionic surfactants such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate and polyethylene glycol distearate, and the like. Also, examples of commercially available products include: KP341 (available from Shin-Etsu Chemical Co., Ltd.); Polyflow No. 75 and Polyflow No. 95 (each available from Kyoeisha Chemical Co., Ltd.); EFTOP EF101, EFTOP EF204, EFTOP EF303 and EFTOP EF352 (each available from Tochem Products Co. Ltd.); Megaface F171, Megaface F172 and Megaface F173 (each available from DIC Corporation); Fluorad FC430, Fluorad FC431, Fluorad FC135 and Fluorad FC93 (each available from Sumitomo 3M Limited); ASAHI GUARD AG710, Surflon S382, Surflon SC101, Surflon SC102, Surflon SC103, Surflon SC104, Surflon SC105 and Surflon SC106 (each available from Asahi Glass Co., Ltd.); and the like.

When the composition for resist underlayer film formation contains the surfactant, the lower limit of the content of the surfactant with respect to 100 parts by mass of the compound (A) is preferably 0.01 parts by mass, more preferably 0.05 parts by mass, and still more preferably 0.1 parts by mass. The upper limit of the content the surfactant with respect to 100 parts by mass of the compound (A) is preferably 10 parts by mass, more preferably 5 parts by mass, and still more preferably 1 part by mass. When the content of the surfactant falls within the above range, the application properties of the composition for resist underlayer film formation may be more improved.

### Adhesion Aid

The adhesion aid is a component that improves adhesiveness to an underlying material. When the composition for resist underlayer film formation contains the adhesion aid, the adhesiveness of the formed resist underlayer film to a substrate, etc., as the underlying material can be improved. The adhesion aid may be used either alone of one type, or in combination of two or more types thereof.

Well-known adhesion aids, for example, may be used as the adhesion aid.

When the composition for resist underlayer film formation contains the adhesion aid, the lower limit of the content of the adhesion aid with respect to 100 parts by mass of the compound (A) is preferably 0.01 parts by mass, more preferably 0.05 parts by mass, and still more preferably 0.1 parts by mass. The upper limit of the content of the adhesion aid with respect to 100 parts by mass of the compound (A) is preferably 10 parts by mass, more preferably 10 parts by mass, and still more preferably 5 parts by mass.

### Preparation Method of Composition for Resist Underlayer Film Formation

The composition for resist underlayer film formation may be prepared by mixing the compound (A) and the solvent (B), and as needed, the acid generating agent (C) and other optional component(s) in a predetermined ratio, and preferably filtering the resulting mixture through a membrane filter having a polar size of about 0.1 μm, etc. The lower limit of the solid content concentration of the composition for resist underlayer film formation is preferably 0.1% by mass, more preferably 1% by mass, still more preferably 2% by mass, and particularly preferably 4% by mass. The upper limit of the solid content concentration of the composition for resist underlayer film formation is preferably 50% by mass, more preferably 30% by mass, still more preferably 15% by mass, and particularly preferably 8% by mass.

### Production Method of Patterned Substrate

The method for producing a patterned substrate according to another embodiment of the present invention includes the steps of:

forming a resist underlayer film on the upper face side of a substrate (hereinafter, may be also referred to as “resist underlayer film-forming step”);

forming a resist pattern on the upper face side of the resist underlayer film (hereinafter, may be also referred to as “resist pattern-forming step”); and

etching at least the resist underlayer film and the substrate, by each separate etching operation using the resist pattern as a mask such that the substrate has a pattern (hereinafter, may be also referred to as “substrate pattern-forming step”). In the method for producing a patterned substrate, the resist underlayer film is formed from the composition for resist underlayer film formation described above.

According to the method for producing a patterned substrate, since the composition for resist underlayer film formation described above is used, a resist underlayer film that is superior in solvent resistance, etching resistance, heat resistance and filling performances can be formed, and the use of the superior resist underlayer film enables a patterned substrate having a superior pattern configuration to be obtained.

### Resist Underlayer Film-Forming Step

In this step, a resist underlayer film is formed on the upper face side of a substrate from the composition for resist underlayer film formation. The formation of the resist underlayer film is typically carried out by applying the composition for resist underlayer film formation on the upper face side of a substrate to provide a coating film, and heating the coating film.

Examples of the substrate include a silicon wafer, a wafer coated with aluminum, and the like. Moreover, the method for applying the composition for resist underlayer film formation on the substrate or the like is not particularly limited, and for example, an appropriate process such as a spin-coating process, a cast-coating process, a roll-coating process may be employed.

Heating of the coating film is typically carried out in an ambient air. The lower limit of the heating temperature is preferably 150° C., more preferably 180° C., and still more preferably 200° C. The upper limit of the heating temperature is preferably 500° C., more preferably 380° C., and still more preferably 300° C. When the heating temperature is less than 150° C., the oxidative crosslinking may not sufficiently proceed, and characteristics necessary for use in the resist underlayer film may not be exhibited. The lower limit of the heating time period is preferably 15 sec, more preferably 30 sec, and still more preferably 45 sec. The upper limit of the heating time period is preferably 1,200 sec, more preferably 600 sec, and still more preferably 300 sec.

The lower limit of an oxygen concentration in the heating is preferably 5 vol %. When the oxygen concentration in the heating is low, the oxidative crosslinking of the resist underlayer film may not sufficiently proceed, and characteristics necessary for use in the resist underlayer film may not be exhibited.

The coating film may be preheated at a temperature of no less than 60° C. and no greater than 250° C. before being heated at a temperature of no less than 150° C. and no greater than 500° C. The lower limit of the heating time period in the preheating is preferably 10 sec, and more preferably 30 sec. The upper limit of the heating time period is preferably 300 sec, and more preferably 180 sec. When the preheating is carried out to preliminarily evaporate a solvent and make the film dense, a dehydrogenation reaction may efficiently proceed.

It is to be noted that in the resist underlayer film formation method, the resist underlayer film is typically formed through the heating of the coating film; however, in a case where the composition for resist underlayer film formation contains a radiation-sensitive acid generating agent, the resist underlayer film may also be formed by hardening the coating film through a combination of an exposure and heating. The radioactive ray used for the exposure may be appropriately selected from: electromagnetic waves such as visible rays, ultraviolet rays, far ultraviolet rays, X-rays and γ radiations; particle rays such as electron beams, molecular beams and ion beams, and the like in accordance with the type of the radiation-sensitive acid generating agent.

The lower limit of the average thickness of the resist underlayer film formed is preferably 0.05 μm, more preferably 0.1 μm, and still more preferably 0.5 μm. The upper limit of the average thickness of the resist underlayer film formed is preferably 5 μm, more preferably 3 μm, and still more preferably 2 μm.

After the resist underlayer film-forming step, the method may further include as needed, the step of forming an intermediate layer (intermediate film) on the upper face side of the resist underlayer film. The intermediate layer as referred to means a layer having a function that is exhibited or not exhibited by the resist underlayer film and/or the resist film in resist pattern formation in order to further enhance the function exhibited by the resist underlayer film and/or the resist film, or to impart to the resist underlayer film and/or the resist film a function not exhibited thereby. For example, when an antireflective film is provided as the intermediate layer, an antireflecting function of the resist underlayer film may be further enhanced.

The intermediate layer may be formed from an organic compound and/or an inorganic oxide. Examples of the organic compound include commercially available products such as: “DUV-42”, “DUV-44”, “ARC-28” and “ARC-29” (each available from Brewer Science); “AR-3” and “AR-19” (each available from Lohm and Haas Company); and the like. Examples of the inorganic oxide include commercially available products such as “NFC SOG01”, “NFC SOG04” and “NFC SOG080” (each JSR Corporation), and the like. Also, polysiloxanes, titanium oxides, alumina oxides, tungsten oxides, and the like that are provided through a CVD process may be used.

The method for providing the intermediate layer is not particularly limited, and for example, a coating method, a CVD technique, or the like may be employed. Of these, the coating method is preferred. In a case where the coating method is employed, the intermediate layer may be successively provided after the resist underlayer film is formed. Moreover, the average thickness of the intermediate layer is appropriately selected in accordance with the function required for the intermediate layer, and the lower limit of the average thickness of the intermediate layer is preferably 10 nm, and more preferably 20 nm. The upper limit of the average thickness of the intermediate layer is preferably 3,000 nm, and more preferably 300 nm.

### Resist Pattern-Forming Step

In this step, a resist pattern is formed on the upper face side of the resist underlayer film. This step may be carried out by, for example, using a resist composition.

When the resist composition is used, specifically, the resist film is formed by applying the resist composition such that a resultant resist film has a predetermined thickness and thereafter subjecting the resist composition to prebaking to evaporate the solvent in the coating film.

Examples of the resist composition include a chemically amplified positive or negative resist composition that contains a radiation-sensitive acid generating agent; a positive resist composition that is constituted with an alkali-soluble resin and a quinone diazide-based photosensitizing agent; a negative resist that is constituted with an alkali-soluble resin and a crosslinking agent; and the like.

The lower limit of the solid content concentration of the resist composition is preferably 0.3% by mass, and more preferably 1% by mass. The upper limit of the solid content concentration of the resist composition is preferably 50% by mass, and more preferably 30% by mass. Moreover, the resist composition is generally used for providing a resist film, for example, after being filtered through a filter with a pore size of 0.2 μm. It is to be noted that a commercially available resist composition may be used as is in this step.

The method for applying the resist composition is not particularly limited, and examples thereof include a spin-coating method, and the like. Moreover, the prebaking temperature may be appropriately adjusted in accordance with the type of the resist composition used, and the like, and the lower limit of the prebaking temperature is preferably 30° C., and more preferably 50° C. The upper limit of the prebaking temperature is preferably 200° C., and more preferably 150° C. The lower limit of the prebaking time period is preferably 10 sec, and more preferably 30 sec. The upper limit of the prebaking time period is preferably 600 sec, and more preferably 300 sec.

Next, the resist film formed is exposed by selective irradiation with a radioactive ray. The radioactive ray used in the exposure may be appropriately selected from: electromagnetic waves such as visible rays, ultraviolet rays, far ultraviolet rays, X-rays and γ radiations; particle rays such as electron beams, molecular beams and ion beams in accordance with the type of the radiation-sensitive acid generating agent used in the resist composition. Among these, far ultraviolet rays are preferred, and a KrF excimer laser beam (248 nm), and an ArF excimer laser beam (193 nm), an F₂ excimer laser beam (wavelength; 157 nm), a Kr₂ excimer laser beam (wavelength: 147 nm), an ArKr excimer laser beam (wavelength: 134 nm) and extreme ultraviolet rays (EUV; wavelength: 13.5 nm, etc.) are more preferred, and a KrF excimer laser beam, an ArF excimer laser beam and EUV are still more preferred.

Post-baking may be carried out after the exposure for the purpose of improving a resolution, a pattern profile, developability, and the like. The post-baking temperature may be appropriately adjusted in accordance with the type of the resist composition used, and the like, and the lower limit of the post-baking temperature is preferably 50° C., and more preferably 70° C. The upper limit of the post-baking temperature is preferably 200° C., and more preferably 150° C. The lower limit of the post-baking time period is preferably 10 sec, and more preferably 30 sec. The upper limit of the post-baking time period is preferably 600 sec, and more preferably 300 sec.

Next, the exposed resist film is developed with a developer solution to form a resist pattern. The development may be either a development with an alkali or a development with an organic solvent. In the case of the development with an alkali, examples of the developer solution include an alkaline aqueous solution that contains sodium hydroxide, potassium hydroxide, sodium carbonate, sodium silicate, sodium metasilicate, ammonia, ethylamine, n-propylamine, diethylamine, di-n-propylamine, triethylamine, methyldiethylamine, dimethylethanolamine, triethanolamine, tetramethylammonium hydroxide, tetraethylammonium hydroxide, pyrrole, piperidine, choline, 1,8-diazabicyclo[5.4.0]-7-undecene, 1,5-diazabicyclo[4.3.0]-5-nonene, or the like. An appropriate amount of a water soluble organic solvent, e.g., an alcohol such as methanol and ethanol, a surfactant, and the like may be added to the alkaline aqueous solution. Alternatively, in the case of the development with an organic solvent, examples of the developer solution include a variety of organic solvents exemplified as the solvent (B) described above, and the like.

A predetermined resist pattern is formed by the development with the developer solution, followed by washing and drying.

In carrying out the resist pattern-forming step, without using the resist composition described above, other process may be employed, for example, a nanoimprint method may be adopted, or a directed self-assembling composition may be used.

### Substrate Pattern-Forming Step

In this step, at least the resist underlayer film and the substrate are etched, by each separate etching operation using the resist pattern as a mask such that the substrate has a pattern. In a case where the intermediate layer is not provided, the resist underlayer film and the substrate are subjected to etching sequentially in this order, whereas in a case where the intermediate layer is provided, the intermediate layer, the resist underlayer film and the substrate are subjected to etching sequentially in this order. The etching procedure may be exemplified by dry-etching, wet-etching, and the like. Of these, the dry-etching is preferred in light of achieving a more superior shape of the substrate pattern. For example, gas plasma such as oxygen plasma and the like may be used in the dry-etching. After the etching, the substrate having a predetermined pattern can be obtained.

### Resist Underlayer Film

The resist underlayer film according to still another embodiment of the present invention is formed from the composition for resist underlayer film formation according to the embodiment of the present invention. Since the resist underlayer film is formed from the composition for resist underlayer film formation described above, the resist underlayer film is superior in solvent resistance, etching resistance, heat resistance and filling performances.

### EXAMPLES

Hereinafter, the embodiments of the present invention will be described in more detail by way of Examples, but the present invention is not in any way limited to these Examples.

### Mw and Mn

The Mw and the Mn of the compound (A) were determined by gel permeation chromatography using GPC columns (“G2000 HXL”×2, and “G3000 HXL”×1) available from Tosoh Corporation, a differential refractometer as a detector and mono-dispersed polystyrene as a standard under analytical conditions involving a flow rate of 1.0 mL/min, an elution solvent of tetrahydrofuran and a column temperature of 40° C.

### Average Thickness of Film

The average thickness of the film was determined using a spectroscopic ellipsometer (“M2000D” available from J. A. WOOLLAM).

### Synthesis of Compound (A)

### Synthesis Example 1

Into a three-neck flask equipped with a thermometer, a condenser and a mechanical stirrer were charged 37.16 g (0.11 mol) of 9,9-bis(4-hydroxyphenyl)fluorene and 2.84 g (0.095 mol) of paraformaldehyde under nitrogen. Next, 0.153 g (0.80 mmol) of p-toluenesulfonic acid monohydrate was dissolved in 58 g of propylene glycol monomethyl ether acetate (PGMEA), then this solution was charged into the three-neck flask, and the mixture was stirred at 95° C. for 6 hrs, whereby the polymerization was allowed to proceed. Thereafter, the polymerization reaction mixture was charged into a large amount of hexane, followed by filtering off the precipitated polymer to obtain a compound (PA-1).

Next, 20 g of the compound (PA-1) obtained as described above, 80 g of N,N-dimethylacetamide and 16.68 g (0.12 mol) of potassium carbonate were charged into a three-neck flask equipped with a thermometer, a condenser and a mechanical stirrer under nitrogen. Next, the mixture was warmed to 80° C., 14.36 g (0.12 mol) of propargyl bromide was added thereto, and then the resulting mixture was stirred for 6 hrs, whereby the reaction was allowed to proceed. Thereafter, 40 g of methyl isobutyl ketone and 80 g of water were added to the reaction solution to carry out a liquid separation operation, and then the organic phase was charged into a large amount of methanol, followed by filtering off the precipitated compound to obtain a compound (A-1). The obtained compound (A-1) had an Mw of 4,500.

### Synthesis Example 2

Into a three-neck flask equipped with a thermometer, a condenser and a mechanical stirrer were charged 37.75 g (0.084 mol) of 9,9-bis(hydroxynaphthyl)fluorene and 2.25 g (0.075 mol) of paraformaldehyde under nitrogen. Next, 0.121 g (0.63 mmol) of p-toluenesulfonic acid monohydrate was dissolved in 58 g of propylene glycol monomethyl ether acetate (PGMEA), then this solution was charged into the three-neck flask, and the mixture was stirred at 95° C. for 6 hrs, whereby the polymerization was allowed to proceed. Thereafter, the polymerization reaction mixture was charged into a large amount of methanol, followed by filtering off the precipitated compound to obtain a compound (PA-2).

Next, 20 g of the polymer (PA-2) obtained as described above, 80 g of N,N′-dimethylacetamide and 13.09 g (0.095 mol) of potassium carbonate were charged into a three-neck flask equipped with a thermometer, a condenser and a mechanical stirrer under nitrogen. Next, the mixture was warmed to 80° C., 11.27 g (0.095 mol) of propargyl bromide was added thereto, and then the resulting mixture was stirred for 6 hrs, whereby the reaction was allowed to proceed. Thereafter, 40 g of methyl isobutyl ketone and 80 g of water were added to the reaction solution to carry out a liquid separation operation, and then the organic phase was charged into a large amount of methanol, followed by filtering off the precipitated compound to obtain a compound (A-2). The obtained compound (A-2) had an Mw of 4,500.

### Synthesis Example 3

Into a three-neck flask equipped with a thermometer, a condenser and a mechanical stirrer were charged 35.16 g (0.16 mol) of 1-hydroxypyrene and 4.84 g (0.16 mol) of paraformaldehyde under nitrogen. Next, 0.245 g (1.29 mmol) of p-toluenesulfonic acid monohydrate was dissolved in 58 g of propylene glycol monomethyl ether acetate (PGMEA), then this solution was charged into the three-neck flask, and the mixture was stirred at 95° C. for 6 hrs, whereby the polymerization was allowed to proceed. Thereafter, the reaction solution was charged into a large amount of methanol, followed by filtering off the precipitated compound to obtain a compound (PA-3).

Next, 20 g of the compound (PA-3) obtained as described above, 80 g of N,N-dimethylacetamide and 13.09 g (0.095 mol) of potassium carbonate were charged into a three-neck flask equipped with a thermometer, a condenser and a mechanical stirrer under nitrogen. Next, the mixture was warmed to 80° C., 11.27 g (0.095 mol) of propargyl bromide was added thereto, and then the resulting mixture was stirred for 6 hrs, whereby the reaction was allowed to proceed. Thereafter, 40 g of methyl isobutyl ketone and 80 g of water were added to the reaction solution to carry out a liquid separation operation, and then the organic phase was charged into a large amount of methanol, followed by filtering off the precipitated compound to obtain a compound (A-3). The obtained compound (A-3) had an Mw of 5,400.

### Synthesis Example 4

Into a three-neck flask equipped with a thermometer, a condenser and a mechanical stirrer were charged 26.42 g (0.075 mol) of 9,9-bis(4-hydroxyphenyl)fluorene, 10.19 g (0.050 mol) of pyrene and 3.40 g (0.113 mol) of paraformaldehyde under nitrogen. Next, 0.182 g (0.96 mmol) of p-toluenesulfonic acid monohydrate was dissolved in 58 g of propylene glycol monomethyl ether acetate (PGMEA), then this solution was charged into the three-neck flask, and the mixture was stirred at 95° C. for 6 hrs, whereby the polymerization was allowed to proceed. Thereafter, the reaction solution was charged into a large amount of hexane, followed by filtering off the precipitated polymer to obtain a compound (PA-4).

Next, 20 g of the compound (PA-4) obtained as described above, 80 g of N,N-dimethylacetamide and 11.96 g (0.087 mol) of potassium carbonate were charged into a three-neck flask equipped with a thermometer, a condenser and a mechanical stirrer under nitrogen. Next, the mixture was warmed to 80° C., 10.29 g (0.087 mol) of propargyl bromide was added thereto, and then the resulting mixture was stirred for 6 hrs, whereby the reaction was allowed to proceed. Thereafter, 40 g of methyl isobutyl ketone and 80 g of water were added to the reaction solution to carry out a liquid separation operation, and then the organic phase was charged into a large amount of methanol, followed by filtering off the precipitated compound to obtain a compound (A-4). The obtained compound (A-4) had an Mw of 3,500.

### Synthesis Example 5

Into a three-neck flask equipped with a thermometer, a condenser and a mechanical stirrer were charged 19.26 g (0.055 mol) of 9,9-bis(4-hydroxyphenyl)fluorene, 8.0 g (0.037 mol) of 1-hydroxypyrene, 8.62 g (0.092 mol) of phenol and 4.13 g (0.137 mol) of paraformaldehyde under nitrogen.

Next, 0.30 g (1.58 mmol) of p-toluenesulfonic acid monohydrate was dissolved in 58 g of propylene glycol monomethyl ether acetate (PGMEA), then this solution was charged into the three-neck flask, and the mixture was stirred at 95° C. for 6 hrs, whereby the polymerization was allowed to proceed. Thereafter, the reaction solution was charged into a large amount of a mixed solution of methanol and water (mass ratio: methanol/water=70/30), followed by filtering off the precipitated polymer to obtain a compound (PA-5).

Next, 20 g of the compound (PA-5) obtained as described above, 80 g of N,N-dimethylacetamide and 18.92 g (0.137 mol) of potassium carbonate were charged into a three-neck flask equipped with a thermometer, a condenser and a mechanical stirrer under nitrogen. Next, the mixture was warmed to 80° C., 16.29 g (0.137 mol) of propargyl bromide was added thereto, and then the resulting mixture was stirred for 6 hrs, whereby the reaction was allowed to proceed. Thereafter, 40 g of methyl isobutyl ketone and 80 g of water were added to the reaction solution to carry out a liquid separation operation, and then the organic phase was charged into a large amount of methanol, followed by filtering off the precipitated compound to obtain a compound (A-5). The obtained compound (A-5) had an Mw of 7,600.

### Synthesis Example 6

Into a three-neck flask equipped with a thermometer, a condenser and a mechanical stirrer were charged 16.15 g (0.046 mol) of 9,9-bis(4-hydroxyphenyl)fluorene, 6.7 g (0.031 mol) of 1-hydroxypyrene, 13.69 g (0.077 mol) of anthracene and 3.46 g (0.115 mol) of paraformaldehyde under nitrogen. Next, 0.182 g (0.96 mmol) of p-toluenesulfonic acid monohydrate was dissolved in 58 g of propylene glycol monomethyl ether acetate (PGMEA), then this solution was charged into the three-neck flask, and the mixture was stirred at 95° C. for 6 hrs, whereby the polymerization was allowed to proceed. Thereafter, the reaction solution was charged into a large amount of a mixed solution of methanol and water (mass ratio: methanol/water=70/30), followed by filtering off the precipitated polymer to obtain a compound (PA-6).

Next, 20 g of the compound (PA-6) obtained as described above, 80 g of N,N-dimethylacetamide and 18.92 g (0.137 mol) of potassium carbonate were charged into a three-neck flask equipped with a thermometer, a condenser and a mechanical stirrer under nitrogen. Next, the mixture was warmed to 80° C., 16.29 g (0.137 mol) of propargyl bromide was added thereto, and then the resulting mixture was stirred for 6 hrs, whereby the reaction was allowed to proceed. Thereafter, 40 g of methyl isobutyl ketone and 80 g of water were added to the reaction solution to carry out a liquid separation operation, and then the organic phase was charged into a large amount of methanol, followed by filtering off the precipitated compound to obtain a compound (A-6). The obtained compound (A-6) had an Mw of 3,200.

### Synthesis Example 7

Into a three-neck flask equipped with a thermometer, a condenser and a mechanical stirrer were charged 17.07 g (0.049 mol) of 9,9-bis(4-hydroxyphenyl)fluorene, 7.09 g (0.032 mol) of 1-hydroxypyrene, 11.71 g (0.081 mol) of 1-naphthol and 4.14 g (0.138 mol) of paraformaldehyde under nitrogen. Next, 0.266 g (1.4 mmol) of p-toluenesulfonic acid monohydrate was dissolved in 58 g of propylene glycol monomethyl ether acetate (PGMEA), then this solution was charged into the three-neck flask, and the mixture was stirred at 95° C. for 6 hrs, whereby the polymerization was allowed to proceed. Thereafter, the reaction solution was charged into a large amount of a mixed solution of methanol and water (mass ratio: methanol/water=70/30), followed by filtering off the precipitated polymer to obtain a compound (PA-7).

Next, 20 g of the compound (PA-7) obtained as described above, 80 g of N,N-dimethylacetamide and potassium carbonate16.90 g (0.122 mol) were charged into a three-neck flask equipped with a thermometer, a condenser and a mechanical stirrer under nitrogen. Next, the mixture was warmed to 80° C., 14.55 g (0.122 mol) of propargyl bromide was added thereto, and then the resulting mixture was stirred for 6 hrs, whereby the reaction was allowed to proceed. Thereafter, 40 g of methyl isobutyl ketone and 80 g of water were added to the reaction solution to carry out a liquid separation operation, and then the organic phase was charged into a large amount of methanol, followed by filtering off the precipitated compound to obtain a compound (A-7). The obtained compound (A-7) had an Mw of 3,900.

### Synthesis Example 8

Into a three-neck flask equipped with a thermometer, a condenser and a mechanical stirrer were charged 21.49 g (0.061 mol) of 9,9-bis(4-hydroxyphenyl)fluorene, 12.41 g (0.061 mol) of pyrene, 2.89 g (0.031 mol) of phenol and 3.22 g (0.107 mol) of paraformaldehyde under nitrogen. Next, 0.251 g (1.32 mmol) of p-toluenesulfonic acid monohydrate was dissolved in 58 g of propylene glycol monomethyl ether acetate (PGMEA), then this solution was charged into the three-neck flask, and the mixture was stirred at 95° C. for 6 hrs, whereby the polymerization was allowed to proceed. Thereafter, the reaction solution was charged into a large amount of a mixed solution of methanol and water (mass ratio: methanol/water=70/30), followed by filtering off the precipitated polymer to obtain a compound (PA-8).

Next, 20 g of the compound (PA-8) obtained as described above, 80 g of N,N-dimethylacetamide and 11.99 g (0.087 mol) of potassium carbonate were charged into a three-neck flask equipped with a thermometer, a condenser and a mechanical stirrer under nitrogen. Next, the mixture was warmed to 80° C., 10.32 g (0.087 mol) of propargyl bromide was added thereto, and then the resulting mixture was stirred for 6 hrs, whereby the reaction was allowed to proceed. Thereafter, 40 g of methyl isobutyl ketone and 80 g of water were added to the reaction solution to carry out a liquid separation operation, and then the organic phase was charged into a large amount of methanol, followed by filtering off the precipitated compound to obtain a compound (A-8). The obtained compound (A-8) had an Mw of 5,600.

### Synthesis Example 9

Into a three-neck flask equipped with a thermometer, a condenser and a mechanical stirrer were charged 9.57 g (0.027 mol) of 9,9-bis(4-hydroxyphenyl)fluorene, 3.97 g (0.018 mol) of 1-hydroxypyrene, 6.56 g (0.046 mol) of 1-naphthol and 19.9 g (0.086 mol) of 1-formylpyrene under nitrogen. Next, 5.19 g (27.3 mmol) of p-toluenesulfonic acid monohydrate was dissolved in 58 g of γ-butyrolactone, then this solution was charged into the three-neck flask, and the mixture was stirred at 130° C. for 9 hrs, whereby the polymerization was allowed to proceed. Thereafter, the reaction solution was charged into a large amount of a mixed solution of methanol and water (mass ratio: methanol/water=70/30), followed by filtering off the precipitated polymer to obtain a compound (PA-9).

Next, 20 g of the compound (PA-9) obtained as described above, 80 g of N,N-dimethylacetamide and 18.92 g (0.137 mol) of potassium carbonate were charged into a three-neck flask equipped with a thermometer, a condenser and a mechanical stirrer under nitrogen. Next, the mixture was warmed to 80° C., 16.29 g (0.137 mol) of propargyl bromide was added thereto, and then the resulting mixture was stirred for 6 hrs, whereby the reaction was allowed to proceed. Thereafter, 40 g of methyl isobutyl ketone and 80 g of water were added to the reaction solution to carry out a liquid separation operation, and then the organic phase was charged into a large amount of methanol, followed by filtering off the precipitated compound to obtain a compound (A-9). The obtained compound (A-9) had an Mw of 1,500.

### Synthesis Example 10

Into a three-neck flask equipped with a thermometer, a condenser and a mechanical stirrer were charged 26.42 g (0.075 mol) of 9,9-bis(4-hydroxyphenyl)fluorene, 10.19 g (0.050 mol) of pyrene and 3.40 g (0.113 mol) of paraformaldehyde under nitrogen. Next, 0.182 g (0.96 mmol) of p-toluenesulfonic acid monohydrate was dissolved in 58 g of propylene glycol monomethyl ether acetate (PGMEA), then this solution was charged into the three-neck flask, and the mixture was stirred at 95° C. for 6 hrs, whereby the polymerization was allowed to proceed. Thereafter, the polymerization reaction mixture was charged into a large amount of hexane, followed by filtering off the precipitated compound to obtain a compound (Pa-1).

Next, 20 g of the compound (Pa-1), 80 g of N,N-dimethylacetamide and 11.96 g (0.087 mol) of potassium carbonate were charged into a three-neck flask equipped with a thermometer, a condenser and a mechanical stirrer under nitrogen. Next, the mixture was warmed to 80° C., 11.68 g (0.087 mol) of 4-bromo-1-butene was added thereto, and then the resulting mixture was stirred for 6 hrs, whereby the reaction was allowed to proceed. Thereafter, 40 g of methyl isobutyl ketone and 80 g of water were added to the reaction solution to carry out a liquid separation operation, and then the organic phase was charged into a large amount of methanol, followed by filtering off the precipitated compound to obtain a compound (a-1). The obtained compound (a-1) had an Mw of 4,000.

### Synthesis Example 11

Into a three-neck flask equipped with a thermometer, a condenser and a mechanical stirrer were charged 25.83 g (0.074 mol) of 9,9-bis(4-hydroxyphenyl)fluorene, 9.96 g (0.049 mol) of pyrene and 4.21 g (0.14 mol) of paraformaldehyde under nitrogen. Next, 0.20 g (1.05 mmol) of p-toluenesulfonic acid monohydrate was dissolved in 58 g of propylene glycol monomethyl ether acetate (PGMEA), then this solution was charged into the three-neck flask, and the mixture was stirred at 95° C. for 6 hrs, whereby the polymerization was allowed to proceed. Thereafter, the polymerization reaction mixture was charged into a large amount of methanol, followed by filtering off the precipitated compound to obtain a compound (CA-1). The obtained compound (CA-1) had an Mw of 11,000.

### Synthesis Example 12

Into a three-neck flask equipped with a thermometer, a condenser and a mechanical stirrer were charged 18.18 g (0.083 mol) of 1-hydroxypyrene, 12.85 g (0.089 mol) of 1-naphthol, 3.35 g (0.036 mol) of phenol and 5.62 g (0.19 mol) of paraformaldehyde under nitrogen. Next, 0.30 g (1.58 mmol) of p-toluenesulfonic acid monohydrate was dissolved in 58 g of propylene glycol monomethyl ether acetate (PGMEA), then this solution was charged into the three-neck flask, and the mixture was stirred at 95° C. for 6 hrs, whereby the polymerization was allowed to proceed. Thereafter, the polymerization reaction mixture was charged into a large amount of a mixed solution of methanol and water (mass ratio: methanol/water=90/10), followed by filtering off the precipitated compound to obtain a compound (CA-2). The obtained compound (CA-2) had an Mw of 5,800.

### Synthesis Example 13

Into a three-neck flask equipped with a thermometer, a condenser and a mechanical stirrer were charged 49.54 g (0.11 mol) of 9,9-bis(hydroxynaphthyl)fluorene and 2.84 g (0.095 mol) of paraformaldehyde under nitrogen. Next, 0.153 g (0.80 mmol) of p-toluenesulfonic acid monohydrate was dissolved in 58 g of propylene glycol monomethyl ether acetate (PGMEA), then this solution was charged into the three-neck flask, and the mixture was stirred at 95° C. for 6 hrs, whereby the polymerization was allowed to proceed. Thereafter, the polymerization reaction mixture was charged into a large amount of methanol, followed by filtering off the precipitated compound to obtain a compound (CA-3). The obtained compound (CA-3) had an Mw of 5,200.

Preparation of Composition for Resist Underlayer Film Formation Components other than the polymer (A) used in the preparation of the composition for resist underlayer film formation are shown below.

(B) Solvent

B-1: propylene glycol monomethyl ether acetate

B-2: cyclohexanone

(C) Acid Generating Agent

C-1: bis(4-t-butylphenyl)iodonium nonafluoro-n-butanesulfonate (a compound represented by the following formula (C-1))

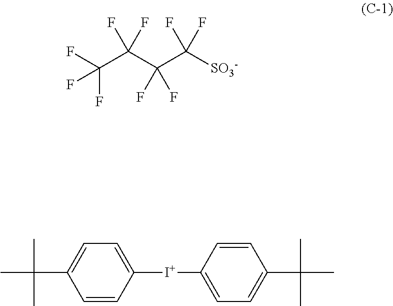

### Example 1

Five parts by mass of (A-1) as the polymer (A) were dissolved in 95 parts by mass of (B-1) as the solvent (B). The obtained solution was filtered through a membrane filter having a pore size of 0.1 μm to prepare a composition for resist underlayer film formation (J-1).

Examples 2 to 13, Reference Example 1, and Comparative Examples 1 to 3 Each composition for resist underlayer film formation was prepared in a similar manner to Example 1 except that the type and the amount of each component used were as specified in Table 1. In Table 1, “-” indicates that the corresponding component was not used.

TABLE 1

| | Composition | | | | | (C) Acid | |
|---|---|---|---|---|---|---|---|
| | for resist | (A) Component | | (B) Solvent | | generating agent | |
| | underlayer | | amount | | | | amount |
| | film | | (parts by | | amount (parts | | (parts by |
| | formation | type | mass) | type | by mass) | type | mass) |
| Example 1 | J-1 | A-1 | 5 | B-1 | 95 | — | — |
| Example 2 | J-2 | A-2 | 5 | B-1 | 95 | — | — |
| Example 3 | J-3 | A-3 | 5 | B-1 | 95 | — | — |
| Example 4 | J-4 | A-4 | 5 | B-1 | 95 | — | — |
| Example 5 | J-5 | A-1 | 5 | B-1 | 94.7 | C-1 | 0.3 |
| Example 6 | J-6 | A-2 | 5 | B-1 | 94.7 | C-1 | 0.3 |
| Example 7 | J-7 | A-3 | 5 | B-1 | 94.7 | C-1 | 0.3 |
| Example 8 | J-8 | A-4 | 5 | B-1 | 94.7 | C-1 | 0.3 |
| Example 9 | J-9 | A-5 | 5 | B-1 | 95 | — | — |
| Example 10 | J-10 | A-6 | 5 | B-1 | 95 | — | — |
| Example 11 | J-11 | A-7 | 5 | B-1 | 95 | — | — |
| Example 12 | J-12 | A-8 | 5 | B-1 | 95 | — | — |
| Example 13 | J-13 | A-9 | 5 | B-1 | 95 | — | — |
| Reference | j-1 | a-1 | 5 | B-1 | 94.7 | C-1 | 0.3 |
| Example 1 | | | | | | | |
| Comparative | CJ-1 | CA-1 | 5 | B-1/B-2 | 66.5/28.5 | — | — |
| Example 1 | | | | | | | |
| Comparative | CJ-2 | CA-2 | 5 | B-1/B-2 | 66.5/28.5 | — | — |
| Example 2 | | | | | | | |
| Comparative | CJ-3 | CA-3 | 5 | B-1/B-2 | 66.5/28.5 | — | — |
| Example 3 | | | | | | | |

Examples 14 to 31, Reference Example 2, and Comparative Examples 4 to 9

Formation of Resist Underlayer Film

The compositions for resist underlayer film formation prepared as described above were each applied on a silicon wafer substrate by way of a spin-coating procedure. Thereafter, baking was carried out at 220° C. and for 60 sec under an ambient air atmosphere to form a resist underlayer film having a thickness of 200 nm, whereby substrates having the resist underlayer film formed thereon were each obtained (Examples 14 to 26 and Comparative Examples 4 to 6). The case of the use of the composition for resist underlayer film formation (j-1) prepared in Reference Example 1 in which the compound (A) had a carbon-carbon double bond-containing group but no carbon-carbon triple bond-containing group was designated as Reference Example 2. In addition, for the compositions for resist underlayer film formation (J-9) to (J-13) and (CJ-1) to (CJ-3) prepared in Examples 9 to 13 and Comparative Examples 1 to 3, substrates having a resist underlayer film formed by baking at 400° C. for 90 sec were also obtained (Examples 27 to 31 and Comparative Examples 7 to 9).

Formation of Resist Underlayer Film on Stepped Substrate

The compositions for resist underlayer film formation prepared as described above were each applied on a silicon wafer stepped substrate (hereinafter, may be also merely referred to as “substrate”) having 70 nm contact holes (CHs) with a depth of 500 nm by way of a spin-coating procedure.

Thereafter, baking was carried out at 220° C. for 60 sec under an ambient air atmosphere to form a resist underlayer film having a thickness of 200 nm, whereby stepped substrates having the resist underlayer film formed thereon were each obtained (Examples 14 to 26 and Comparative Examples 4 to 6). In addition, for the compositions for resist underlayer film formation (J-9) to (J-13) and (CJ-1) to (CJ-3) prepared in Examples 9 to 13 and Comparative Examples 1 to 3, stepped substrates having the resist underlayer film formed by baking at 400° C. for 90 sec were obtained (Examples 27 to 31 and Comparative Examples 7 to 9).

### Evaluations

For the substrates with a resist underlayer film and stepped substrates with a resist underlayer film obtained as described above, evaluations were each made according to the following procedures. The results of the evaluations are shown in Table 2. In Table 2, “-” indicates that the evaluation was not made due to inferior performance of the resist underlayer film and difficulty in making the evaluation.

### Solvent Resistance

The substrate with the resist underlayer film obtained as described above was immersed in cyclohexanone (at room temperature) for 1 min. The average film thickness was measured before and after the immersion. The average film thickness before the immersion was designated as X0 and the average film thickness after the immersion was designated as X, and the absolute value of a numerical value determined according to (X−X0)×100/X0 was calculated and designated as the rate of change of film thickness (%). The solvent resistance was evaluated to be: “A” (favorable) in a case where the rate of change of film thickness was less than 1%; “B” (somewhat favorable) in a case where the rate of change of film thickness was no less than 1% and less than 5%; and “C” (unfavorable) in a case where the rate of change of film thickness was no less than 5%.

### Etching Resistance

The substrate with the resist underlayer film obtained as described above was treated in an etching apparatus (“TACTRAS” available from Tokyo Electron Limited) under conditions involving: CF₄/Ar=110/440 sccm, PRESS.=30 MT, HF RF=500 W, LF RF=3,000 W, DCS=−150 V, RDC=50%, and 30 sec. An etching rate (nm/min) was calculated based on the average film thickness before the treatment and the average film thickness after the treatment, and the ratio of the etching rate of the film according to Examples with respect to that of Comparative Example 4 was calculated. The etching resistance was evaluated to be: “A” (extremely favorable) in a case where the proportion was no less than 0.95 and less than 0.98; “B” (favorable) in a case where the proportion was no less than 0.98 and less than 1.00; and “C” (unfavorable) in a case where the proportion was no less than 1.00.

### Heat Resistance

The composition for resist underlayer film formation prepared as described above was spin-coated on a silicon wafer having a diameter of 8 inches to provide a resist underlayer film. Thereafter, the resist underlayer film was heated at 400° C. for 150 sec. A powder was collected from the substrate, and then the powder was heated in a TG-DTA apparatus under a nitrogen atmosphere with a rate of temperature rise of 10° C./min. The mass loss rate (%) in the heating was designated as heat resistance. The smaller heat resistance indicates that the resist underlayer film is more favorable (i.e., more superior in heat resistance) as there are less sublimated matter and resist underlayer film degradation products generated during the heating of the resist underlayer film. The heat resistance was evaluated to be: “A” (extremely favorable) in a case where the mass loss rate was no less than 0% and less than 5%; “B” (favorable) in a case where the mass loss rate was no less than 5% and less than 10%; and “C” (unfavorable) in a case where the mass loss rate was no less than 10%.

### Filling Performance

The stepped substrate with the resist underlayer film obtained as described above was evaluated for the presence or absence of a void. The evaluation of “A” (favorable) was made in a case where any void was not found, whereas the evaluation of “B” (unfavorable) was made in a case where a void was found.

TABLE 2

| | Composition | Baking | | | | |
|---|---|---|---|---|---|---|
| | for resist | conditions in | | | | |
| | underlayer | resist | | | | |
| | film | underlayer film | Solvent | Etching | Heat | Filling |
| | formation | formation | resistance | resistance | resistance | performance |
| Example 14 | J-1 | 220° C./60 s | A | A | A | A |
| Example 15 | J-2 | 220° C./60 s | A | A | A | A |
| Example 16 | J-3 | 220° C./60 s | A | A | A | A |
| Example 17 | J-4 | 220° C./60 s | A | A | A | A |
| Example 18 | J-5 | 220° C./60 s | A | A | A | A |
| Example 19 | J-6 | 220° C./60 s | A | A | A | A |
| Example 20 | J-7 | 220° C./60 s | A | A | A | A |
| Example 21 | J-8 | 220° C./60 s | A | A | A | A |
| Example 22 | J-9 | 220° C./60 s | A | A | A | A |
| Example 23 | J-10 | 220° C./60 s | A | A | A | A |
| Example 24 | J-11 | 220° C./60 s | A | A | A | A |
| Example 25 | J-12 | 220° C./60 s | A | A | A | A |
| Example 26 | J-13 | 220° C./60 s | A | A | A | A |
| Example 27 | J-9 | 400° C./90 s | A | A | A | A |
| Example 28 | J-10 | 400° C./90 s | A | A | A | A |
| Example 29 | J-11 | 400° C./90 s | A | A | A | A |
| Example 30 | J-12 | 400° C./90 s | A | A | A | A |
| Example 31 | J-13 | 400° C./90 s | A | A | A | A |
| Reference | j-1 | 220° C./60 s | A | A | C | A |
| Example 2 | | | | | | |
| Comparative | CJ-1 | 220° C./60 s | C | — | — | — |
| Example 4 | | | | | | |
| Comparative | CJ-2 | 220° C./60 s | C | — | — | — |
| Example 5 | | | | | | |
| Comparative | CJ-3 | 220° C./60 s | C | — | — | — |
| Example 6 | | | | | | |
| Comparative | CJ-1 | 400° C./90 s | A | C | A | B |
| Example 7 | | | | | | |
| Comparative | CJ-2 | 400° C./90 s | A | C | A | B |
| Example 8 | | | | | | |
| Comparative | CJ-3 | 400° C./90 s | A | C | A | B |
| Example 9 | | | | | | |

As is clear from the results shown in Table 2, the compositions for resist underlayer film formation of Examples enable the use of PGMEA or the like as a solvent, and can form a resist underlayer film that is superior in solvent resistance, etching resistance, heat resistance and filling performances.

The composition for resist underlayer film formation according to the embodiment of the present invention enables the use of PGMEA or the like as a solvent, and can form a resist underlayer film that is superior in solvent resistance, etching resistance, heat resistance and filling performances. The resist underlayer film according to the still another embodiment of the present invention is superior in solvent resistance, etching resistance, heat resistance and filling performances. The method for producing a patterned substrate according to the another embodiment of the present invention enables a patterned substrate having a superior pattern configuration to be obtained using the superior resist underlayer film formed thus. Therefore, these can be suitably used in manufacture of semiconductor devices, and the like in which further progress of miniaturization is expected in the future.

Obviously, numerous modifications and variations of the present invention are possible in light of the above teachings. It is therefore to be understood that within the scope of the appended claims, the invention may be practiced otherwise than as specifically described herein.

1. A composition comprising:
a compound which comprises:
a carbon-carbon triple bond-containing group; and
at least one partial structure having an aromatic ring, a total number of benzene nuclei constituting the aromatic ring in the at least one partial structure being no less than 4; and
a solvent.

2. The composition according to claim 1, wherein the at least one partial structure comprises a partial structure represented by formula (1): 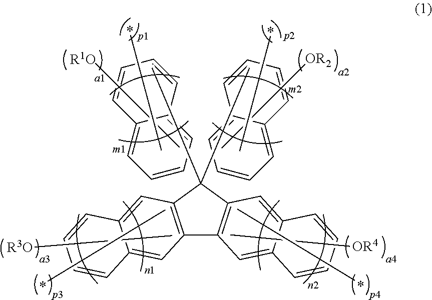
wherein, in the formula (1),
R¹ to R⁴ each independently represent a hydrogen atom, a monovalent carbon-carbon triple bond-containing group or a monovalent carbon-carbon double bond-containing group;
m1 and m2 are each independently an integer of 0 to 2;
at and a2 are each independently an integer of 0 to 9;
n1 and n2 are each independently an integer of 0 to 2;
a3 and a4 are each independently an integer of 0 to 8,
wherein in a case where R¹ to R⁴ are each present in a plurality of number, a plurality of R¹s are identical or different, a plurality of R²s are identical or different, a plurality of R³s are identical or different, and a plurality of R⁴s are identical or different;
p1 and p2 are each independently an integer of 0 to 9;
p3 and p4 are each independently an integer of 0 to 8,
wherein a sum of p1, p2, p3 and p4 is no less than 0, a sum of a1 and p1 and a sum of a2 and p2 are each no greater than 9, and a sum of a3 and p3 and a sum of a4 and p4 are each no greater than 8; and
* denotes a binding site to a moiety other than the partial structure represented by the formula (1) in the compound.

3. The composition according to claim 2, wherein the sum of p1, p2, p3 and p4 in the formula (1) is no less than 1, and at least one of R¹ to R⁴ represents the monovalent carbon-carbon triple bond-containing group.

4. The composition according to claim 3, wherein the monovalent carbon-carbon triple bond-containing group is a propargyl group.

5. The composition according to claim 1, wherein the at least one partial structure comprises a partial structure represented by formula (2): 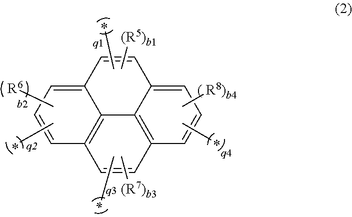
wherein, in the formula (2),
R⁵ to R⁸ each independently represent an alkyl group, a hydroxy group, an alkoxy group, a monovalent carbon-carbon triple bond-containing group or a monovalent carbon-carbon double bond-containing group;
b1 and b3 are each independently an integer of 0 to 2;
b2 and b4 are each independently an integer of 0 to 3,
wherein in a case where R⁵ to R⁸ are each present in a plurality of number, a plurality of R⁵s are identical or different, a plurality of R⁶s are identical or different, a plurality of R⁷s are identical or different, and
a plurality of R⁸s are identical or different;
q1 and q3 are each independently an integer of 0 to 2;
q2 and q4 are each independently an integer of 0 to 3,
wherein a sum of q1, q2, q3 and q4 is no less than 0, a sum of b1 and q1 and a sum of b3 and q3 are each no greater than 2, and a sum of b2 and q2 and a sum of b4 and q4 are each no greater than 3; and
* denotes a binding site to a moiety other than the partial structure represented by the formula (2) in the compound.

6. The composition according to claim 1, wherein the at least one partial structure comprises a first partial structure represented by formula (1) and a second partial structure represented by formula (2), 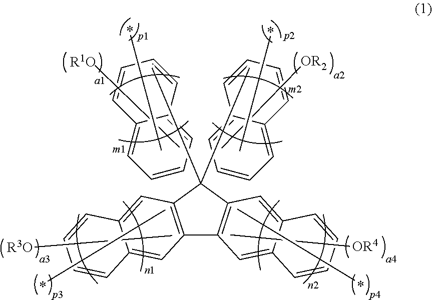
wherein, in the formula (1),
R¹ to R⁴ each independently represent a hydrogen atom, a monovalent carbon-carbon triple bond-containing group or a monovalent carbon-carbon double bond-containing group;
m1 and m2 are each independently an integer of 0 to 2;
a1 and a2 are each independently an integer of 0 to 9;
n1 and n2 are each independently an integer of 0 to 2;
a3 and a4 are each independently an integer of 0 to 8,
wherein in a case where R¹ to R⁴ are each present in a plurality of number, a plurality of R¹s are identical or different, a plurality of R²s are identical or different, a plurality of R³s are identical or different, and a plurality of R⁴s are identical or different;
p1 and p2 are each independently an integer of 0 to 9;
p3 and p4 are each independently an integer of 0 to 8,
wherein a sum of p1, p2, p3 and p4 is no less than 0, a sum of a1 and p1 and a sum of a1 and p2 are each no greater than 9, and a sum of a3 and p3 and a sum of a4 and p4 are each no greater than 8; and
* denotes a binding site to a moiety other than the first partial structure represented by the formula (1) in the compound, and 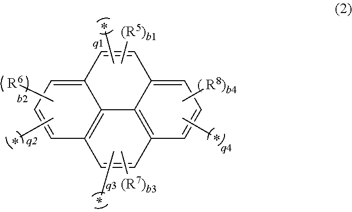
wherein, in the formula (2),
R⁵ to R⁸ each independently represent an alkyl group, a hydroxy group, an alkoxy group, a monovalent carbon-carbon triple bond-containing group or a monovalent carbon-carbon double bond-containing group;
b1 and b3 are each independently an integer of 0 to 2;
b2 and b4 are each independently an integer of 0 to 3,
wherein in a case where R⁵ to R⁸ are each present in a plurality of number, a plurality of R⁵s are identical or different, a plurality of R⁶s are identical or different, a plurality of R⁷s are identical or different, and a plurality of R⁸s are identical or different;
q1 and q3 are each independently an integer of 0 to 2;
q2 and q4 are each independently an integer of 0 to 3,
wherein a sum of q1, q2, q3 and q4 is no less than 0, a sum of b1 and q1 and a sum of b3 and q3 are each no greater than 2, and a sum of b2 and q2 and a sum of b4 and q4 are each no greater than 3; and
* denotes a binding site to a moiety other than the second partial structure represented by the formula (2) in the compound.

7. The composition according to claim 5, wherein the sum of q1, q2, q3 and q4 in the formula (2) is no less than 1, and at least one of R⁵ to R⁸ represents the monovalent carbon-carbon triple bond-containing group.

8. The composition according to claim 7, wherein the monovalent carbon-carbon triple bond-containing group is a propargyloxy group.

9. The composition according to claim 1, wherein the at least one partial structure comprises a plurality of partial structures, and the plurality of partial structures are linked to one another through a linking group derived from an aldehyde.

10. The composition according to claim 1, wherein a molecular weight of the compound is no less than 1,000 and no greater than 10,000.

11. The composition according to claim 1, wherein the solvent comprises a polyhydric alcohol partial ether acetate solvent.

12. A resist underlayer film formed from the composition according to claim 1.

13. A method for producing a patterned substrate, comprising:
applying the composition according to claim 1 on an upper face side of a substrate to form a resist underlayer film;
forming a resist pattern on an upper face side of the resist underlayer film; and
etching the resist underlayer film and the substrate, by each separate etching operation using the resist pattern as a mask such that the substrate has a pattern.
